(19) United States
(12) Patent Application Publication
(10) Pub. No.: US 2024/0128293 A1
(43) Pub. Date: Apr. 18, 2024

(54) IMAGING DEVICE

(71) Applicant: SONY SEMICONDUCTOR SOLUTIONS CORPORATION, Kanagawa (JP)

(72) Inventors: Itaru OSHIYAMA, Kanagawa (JP); Ryo OGATA, Kanagawa (JP)

(73) Assignee: SONY SEMICONDUCTOR SOLUTIONS CORPORATION, Kanagawa (JP)

(21) Appl. No.: 17/768,405

(22) PCT Filed: Jul. 15, 2020
(86) PCT No.: PCT/JP2020/027438

§ 371 Date: Apr. 12, 2022

(30) Foreign Application Priority Data
Oct. 24, 2019 (JP) 2019-193308

(51) Int. Cl. H01L 27/146

(52) U.S. Cl. CPC H01L 27/14625; H01L 27/1463

(57) ABSTRACT

There is provided an imaging device including: a semiconductor substrate including a photoelectric conversion section provided for each of pixels that are two-dimensionally arranged, in which the photoelectric conversion section performs photoelectric conversion on incident light; and an uneven structure provided on a light-receiving-side principal surface of the semiconductor substrate, in which the uneven structure includes a plurality of pillars arranged at a period shorter than a wavelength of light belonging to a visible light band.

### CROSS REFERENCE TO RELATED APPLICATIONS

This application claims the benefit of Japanese Priority Patent Application JP2019-193308 filed Oct. 24, 2019, the entire contents of which are incorporated herein by reference.

### TECHNICAL FIELD

The present disclosure relates to an imaging device.

### BACKGROUND ART

In recent years, a technique for suppressing flare or ghost has undergone development in imaging devices. Flare or ghost occurs due to, for example, incident light entering a photoelectric conversion section inside an imaging device through an unintended light path after having been reflected inside the imaging device.

Therefore, in order to reduce the reflection of incident light inside the imaging device, a technique has been contemplated which adopts an uneven structure (referred to also as a moth-eye structure) according to a wavelength region of incident light on one principal surface of a semiconductor substrate provided with the photoelectric conversion section (for example, PTL 1). The moth-eye structure is the uneven structure arranged at a period smaller than a wavelength of light in the visible light band, and is able to cause a refractive index for incident light to continuously vary, thus making it possible to reduce the reflection of incident light.

### CITATION LIST

### Patent Literature

[PTL 1] International Publication No. WO2015/001987

### SUMMARY

### Technical Problem

Here, a reflection-suppressing effect of a moth-eye structure depends on a specific shape of its uneven structure. It is therefore desired to further suppress reflection of incident light inside an imaging device by contemplating a specific shape of an uneven structure of a moth-eye structure and to further suppress the incident light entering a photoelectric conversion sections through an unintended light path.

It is therefore desirable to provide an imaging device in which occurrence of flare, ghost, or the like is further suppressed.

### Solution to Problem

An imaging device according to an embodiment of the present disclosure includes: a semiconductor substrate including a photoelectric conversion section provided for each of pixels that are two-dimensionally arranged, in which the photoelectric conversion section performs photoelectric conversion on incident light; and an uneven structure provided on a light-receiving-side principal surface of the semiconductor substrate, in which the uneven structure includes a plurality of pillars arranged at a period smaller than a wavelength of light belonging to a visible light band. Each of the pillars has an aspect ratio of 1 or more as determined by dividing a height of each of the pillars by a diameter of a base of each of the pillars in an arbitrary direction.

An imaging device according to an embodiment of the present disclosure includes: a semiconductor substrate including a photoelectric conversion section provided for each of pixels that are two-dimensionally arranged, in which the photoelectric conversion section performs photoelectric conversion on incident light; and an uneven structure provided on a light-receiving-side principal surface of the semiconductor substrate, in which the uneven structure includes a plurality of pillars arranged at a period smaller than a wavelength of light belonging to a visible light band. Each of the pillars has a flat part at a tip thereof, and the flat part has a diameter of 10 nm or less in an arbitrary direction.

An imaging device according to an embodiment of the present disclosure includes: a semiconductor substrate including a photoelectric conversion section provided for each of pixels that are two-dimensionally arranged, in which the photoelectric conversion section performs photoelectric conversion on incident light; and an uneven structure provided on a light-receiving-side principal surface of the semiconductor substrate, in which the uneven structure includes a plurality of pillars arranged at a period smaller than a wavelength of light belonging to a visible light band. Each of the pillars has an aspect ratio of 1 or more as determined by dividing a height of each of the pillars by a diameter of a base of each of the pillars in an arbitrary direction, or a flat part at a tip of each of the pillars has a diameter of 10 nm or less in an arbitrary direction. This makes it possible, for example, to further suppress reflection of incident light on the light-receiving-side principal surface of the semiconductor substrate.

### BRIEF DESCRIPTION OF DRAWINGS

FIG. 1 is an explanatory schematic diagram that describes a schematic configuration of an imaging device to which the technique according to the present disclosure is applied.

FIG. 2 is a vertical cross-sectional view of a configuration of pixels in an imaging device according to a first embodiment of the present disclosure.

FIG. 3A is a vertical cross-sectional view of a specific shape of an uneven structure in the first embodiment.

FIG. 3B is a graph diagram illustrating a result of simulation of a light re-flection-suppressing effect produced by the uneven structure.

FIG. 4A is a vertical cross-sectional view of a variation of a specific shape of the uneven structure in the first embodiment.

FIG. 4B is a vertical cross-sectional view of a variation of the specific shape of the uneven structure in the first embodiment.

FIG. 4C is a vertical cross-sectional view of a variation of the specific shape of the uneven structure in the first embodiment.

FIG. 5 is a vertical cross-sectional view of a configuration of pixels in an imaging device according to a modification example of the first embodiment.

FIG. 6A is a vertical cross-sectional view that describes one of steps of forming the uneven structure in the imaging device according to the first embodiment.

FIG. 6B is a vertical cross-sectional view that describes one of the steps of forming the uneven structure in the imaging device according to the first embodiment.

FIG. 6C is a vertical cross-sectional view that describes one of the steps of forming the uneven structure in the imaging device according to the first embodiment.

FIG. 6D is a vertical cross-sectional view that describes one of the steps of forming the uneven structure in the imaging device according to the first embodiment.

FIG. 6E is a vertical cross-sectional view that describes one of the steps of forming the uneven structure in the imaging device according to the first embodiment.

FIG. 6F is a vertical cross-sectional view that describes one of the steps of forming the uneven structure in the imaging device according to the first embodiment.

FIG. 6G is a vertical cross-sectional view that describes one of the steps of forming the uneven structure in the imaging device according to the first embodiment.

FIG. 7 is a vertical cross-sectional view of a configuration of pixels in an imaging device according to a second embodiment of the present disclosure.

FIG. 8 is a vertical cross-sectional view of a configuration of pixels in an imaging device according to a first modification example of the second embodiment.

FIG. 9 is a vertical cross-sectional view of a configuration of pixels in an imaging device according to a second modification example of the second embodiment.

FIG. 10 is a vertical cross-sectional view of a configuration of pixels in an imaging device according to a third modification example of the second embodiment.

FIG. 11 is a vertical cross-sectional view of the configuration of the pixels in the imaging device according to the third modification example of the second embodiment.

FIG. 12A is a vertical cross-sectional view that describes one of steps of forming the imaging device according to the second embodiment.

FIG. 12B is a vertical cross-sectional view that describes one of the steps of forming the imaging device according to the second embodiment.

FIG. 12C is a vertical cross-sectional view that describes one of the steps of forming the imaging device according to the second embodiment.

FIG. 12D is a vertical cross-sectional view that describes one of the steps of forming the imaging device according to the second embodiment.

FIG. 12E is a vertical cross-sectional view that describes one of the steps of forming the imaging device according to the second embodiment.

FIG. 12F is a vertical cross-sectional view that describes one of the steps of forming the imaging device according to the second embodiment.

FIG. 13 is a vertical cross-sectional view of an example of a configuration of pixels in an imaging device according to a third embodiment of the present disclosure.

FIG. 14 is a vertical cross-sectional view of a modification example of the configuration of the pixels in the imaging device according to the third embodiment.

FIG. 15 is a vertical cross-sectional view of an example of a configuration of pixels in an imaging device according to a fourth embodiment of the present disclosure.

FIG. 16 is a vertical cross-sectional view of a modification example of the configuration of the pixels in the imaging device according to the fourth embodiment.

FIG. 17 is a vertical cross-sectional view of an example of a configuration of pixels in an imaging device according to a fifth embodiment of the present disclosure.

FIG. 18 is a vertical cross-sectional view of a modification example of the configuration of the pixels in the imaging device according to the fifth embodiment.

FIG. 19 is a vertical cross-sectional view of an example of a configuration of pixels in an imaging device according to a sixth embodiment of the present disclosure.

FIG. 20 is a vertical cross-sectional view of a modification example of the configuration of the pixels in the imaging device according to the sixth embodiment.

FIG. 21 is a block diagram illustrating an example of a schematic configuration of an imaging system including an imaging device according to an embodiment of the present disclosure.

FIG. 22 is a flowchart diagram illustrating an example of an imaging operation of the imaging system illustrated in FIG. 21.

FIG. 23 is a block diagram depicting an example of schematic configuration of a vehicle control system.

FIG. 24 is a diagram of assistance in explaining an example of installation positions of an outside-vehicle information detecting section and an imaging section.

FIG. 25 is a view depicting an example of a schematic configuration of an endoscopic surgery system.

FIG. 26 is a block diagram depicting an example of a functional configuration of a camera head and a camera control unit (CCU).

### DESCRIPTION OF EMBODIMENTS

The following describes embodiments of the present disclosure in detail with reference to the drawings. The embodiments described below are merely specific examples of the present disclosure, and the technique according to the present disclosure is not limited to the modes described below. Furthermore, properties of constituent elements of the present disclosure, such as arrangement, dimensions, and dimension ratios, are not limited to the modes illustrated in the drawings.

For the convenience of description, a direction in which substrates or layers are stacked may be referred to as an up-down direction, and a direction in which a layer is laminated onto a substrate or another layer may be referred to as an up direction, in some cases, in the embodiments described below.

It is to be noted that the description is given in the following order.

1. Schematic Configuration of Imaging Device

2. First Embodiment

2.1. Configuration of Pixel

2.2. Modification Example

2.3. Formation Method of Uneven Structure

3. Second Embodiment

3.1. Configuration of Pixel

3.2. Modification Examples

3.3. Manufacturing Method

4. Third Embodiment

5. Fourth Embodiment

6. Fifth Embodiment

7. Sixth Embodiment

8. Application Examples

### 1. Schematic Configuration of Imaging Device

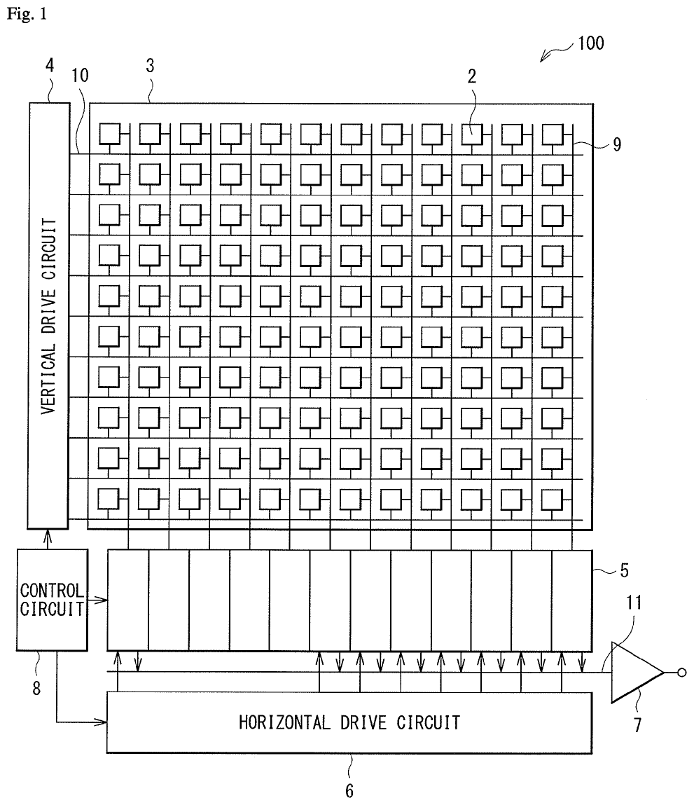

First, a schematic configuration of an imaging device to which the technique according to the present disclosure is applied is described with reference to FIG. 1. FIG. 1 is an explanatory schematic diagram that describes a schematic configuration of an imaging device to which the technique according to the present disclosure is applied.

As illustrated in FIG. 1, an imaging device 100 to which the technique according to the present disclosure is applied may include, for example, a pixel array section 3 in which pixels 2 are two-dimensionally arranged in matrix, a vertical drive circuit 4, a column signal processing circuit 5, a horizontal drive circuit 6, an output circuit 7, and a control circuit 8.

The pixel array section 3, the vertical drive circuit 4, the column signal processing circuit 5, the horizontal drive circuit 6, the output circuit 7, and the control circuit 8 are provided, for example, on a semiconductor substrate such as a silicon substrate. Furthermore, the pixel array section 3, the vertical drive circuit 4, the column signal processing circuit 5, the horizontal drive circuit 6, the output circuit 7, and the control circuit 8 may be provided on a single semiconductor substrate or may be separately provided on two or more semiconductor substrates.

Each of the pixels 2 includes a photoelectric conversion section, and a pixel circuit that converts a charge generated by the photoelectric conversion section to a pixel signal. The pixel circuit may include, for example, a transfer transistor, an amplification transistor, a selection transistor, and a reset transistor. The photoelectric conversion section may include, for example, a photodiode, and the pixel circuit includes four MOSFETs (Metal-Oxide-Semiconductor Field-Effect Transistors).

It is to be noted that the pixels 2 may be provided in a pixel-sharing structure. The pixel-sharing structure is a structure in which a plurality of pixels 2 adjacent to each other shares a portion or all of a pixel circuit. For example, the plurality of adjacent pixels 2 may share a downstream circuit of respective transfer transistors thereof. Specifically, the plurality of adjacent pixels 2 may each include a photodiode, a transfer transistor, a single floating diffusion (floating diffusion region: FD) to be shared, a single amplification transistor to be shared, a single selection transistor to be shared, and a single reset transistor to be shared.

The control circuit 8 controls an operation of each section of the imaging device 100. Specifically, on the basis of vertical synchronizing signals, horizontal synchronizing signals, and a master clock, the control circuit 8 generates clock signals and control signals, which serve as criteria of operations of components such as the vertical drive circuit 4, the column signal processing circuit 5, and the horizontal drive circuit 6. Furthermore, the control circuit 8 also outputs the clock signals and the control signals that are generated to the vertical drive circuit 4, the column signal processing circuit 5, the horizontal drive circuit 6, and the like.

The vertical drive circuit 4 may include, for example, a shift register. The vertical drive circuit 4 selects a pixel drive wiring line 10, and supplies the selected pixel drive wiring line 10 with a pulse signal to thereby drive the pixels 2 on a row basis. Specifically, the vertical drive circuit 4 sequentially selects and scans, in a vertical direction, the pixels 2 included in the pixel array section 3 on a row basis. This enables the vertical drive circuit 4 to extract a pixel signal from each of the pixels 2 according to the amount of charges generated through photoelectric conversion and to supply the pixel signals to the column signal processing circuit 5.

The column signal processing circuit 5 is provided for each column of the pixels 2 of the pixel array section 3, and performs a process such as denoising on the pixel signals outputted from the pixels 2 for each column of the pixels 2. For example, the column signal processing circuits 5 may perform a process such as a correlated double sampling (CDS) process and an AD (Analog-Digital) conversion process on the pixel signals to remove a fixed pattern noise unique to the pixels 2.

The horizontal drive circuit 6 may include, for example, a shift register. The horizontal drive circuit 6 sequentially selects the column signal processing circuits 5 by sequentially outputting horizontal scanning pulses to cause a pixel signal to be outputted from each of the column signal processing circuits 5 to a horizontal signal line 11.

The output circuit 7 outputs, to the outside of the imaging device 100, the pixel signals sequentially supplied from each of the column signal processing circuits 5 through the horizontal signal line 11. For example, the output circuit 7 may perform various types of digital signal processing, such as buffering, black level adjustment, or column variation correction, on the pixel signals supplied from each of the column signal processing circuits 5, and thereafter output the thus processed pixel signals to the outside of the imaging device 100.

The imaging device 100 having the above-described configuration is a CMOS (Complementary MOS) image sensor of so-called column AD system, in which the column signal processing circuit 5 that performs the CDS process and the AD conversion process is provided for each column of the pixels 2.

The technique according to the present disclosure may be applied, for example, to the imaging device 100 having the above-described configuration. According to the technique of the present disclosure, it is possible to suppress reflection of incident light inside the imaging device 100 by adopting an uneven structure having a specific shape on a light-receiving-side principal surface of a semiconductor substrate including the photoelectric conversion section.

### 2. First Embodiment

### 2.1. Configuration of Pixels

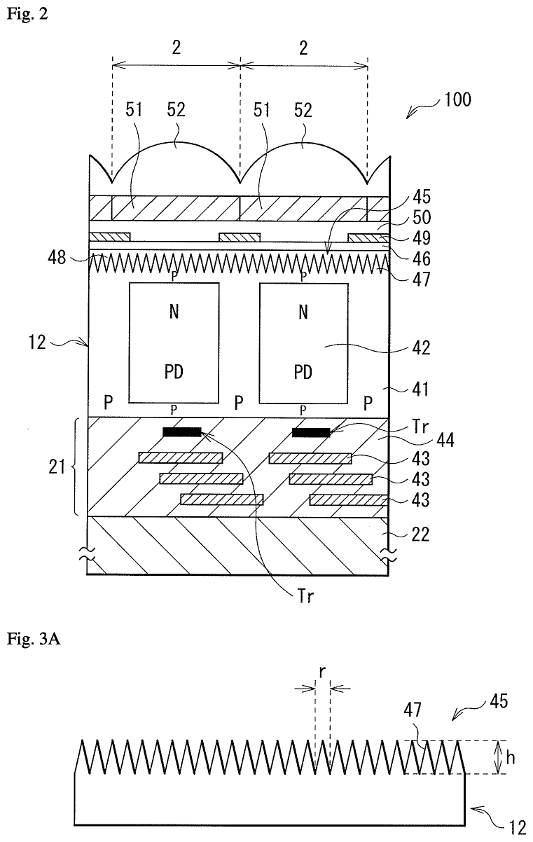

The following describes a configuration of the pixels 2 in the imaging device 100 according to a first embodiment of the present disclosure with reference to FIG. 2. FIG. 2 is a vertical cross-sectional view of the configuration of the pixels 2 in the imaging device 100 according to the present embodiment.

As illustrated in FIG. 2, the imaging device 100 may include, for example, a semiconductor substrate 12, a multi-layer wiring layer 21, and a support substrate 22.

The semiconductor substrate 12 is a substrate including a semiconductor such as silicon. The semiconductor substrate 12 may include, for example, inside a semiconductor region 41 of first electrically-conductive type (e.g., p-type), a semiconductor region 42 of second electrically-conductive type (e.g., n-type) for each of the pixels 2. Thus, a photodiode PD that functions as the photoelectric conversion section is provided for each of the pixels 2 in the semiconductor substrate 12. Furthermore, the semiconductor region 41 of the first electrically-conductive type (e.g., p-type) that functions as a hole accumulation region for suppressing a dark current is provided within two principal surfaces of the semiconductor substrate 12, which are opposed to each other in a thickness direction of the semiconductor substrate 12.

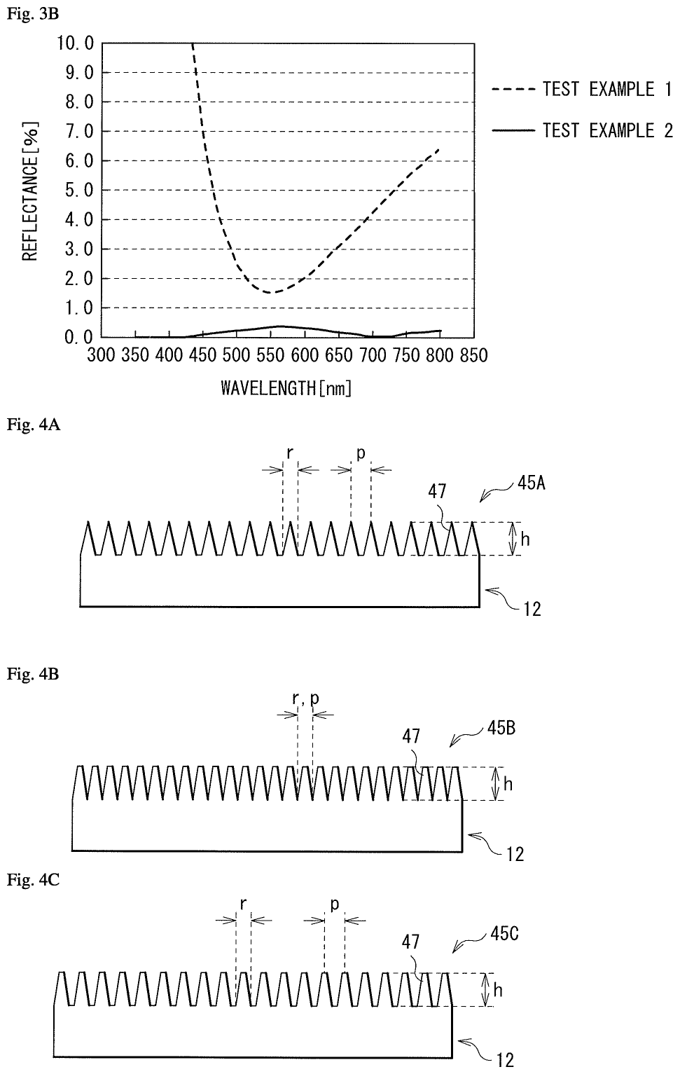

The light-receiving-side principal surface, on which light is incident, of the semiconductor substrate 12 of the imaging device 100 according to the present embodiment is provided with a plurality of pillars 47 arranged at a period smaller than a wavelength of light belonging to the visible light band. The plurality of pillars 47 forms an uneven structure 45 that functions as a moth-eye structure to thereby make it possible to suppress reflection of incident light on the light-receiving-side principal surface of the semiconductor substrate 12. Specific shapes of the pillars 47 and the uneven structure 45 are described below with reference to FIGS. 3A to 4C.

The multi-layer wiring layer 21 includes a plurality of wiring layers 43 and a plurality of interlayer insulating layers 44 that are stacked on the other principal surface of the semiconductor substrate 12, which is opposite to the light-receiving-side principal surface with respect to the semiconductor substrate 12. The multi-layer wiring layer 21 is provided with wiring lines that electrically couple transistors Tr such as transfer transistors, amplification transistors, selection transistors, and reset transistors included in the pixel circuits, with other transistors Tr together.

The support substrate 22 is provided on a surface, of the multi-layer wiring layer 21, opposed to a surface having the semiconductor substrate 12 stacked thereon (i.e., on a surface of the multi-layer wiring layer 21 opposite to a light-receiving-side surface with respect to the multi-layer wiring layer 21). The support substrate 22 is provided to support the multi-layer wiring layer 21 and the semiconductor substrate 12 and to ensure an overall stiffness of the imaging device 100, for example. The support substrate 22 may be any of a semiconductor substrate, a quartz substrate, a glass substrate, or a resin substrate.

Meanwhile, a pinning layer 48 including a high dielectric material having a negative fixed charge is provided on the light-receiving-side surface of the semiconductor substrate 12, to cover the semiconductor region 41 of the first electrically-conductive type. Specifically, the pinning layer 48 may be provided to fill an uneven portion of the uneven structure 45 provided on the light-receiving-side principal surface of the semiconductor substrate 12 as illustrated in FIG. 2, or may be provided along the uneven portion of the uneven structure 45. The pinning layer 48 is provided to have a negative fixed charge, and forms a region where a positive charge (i.e., holes) is accumulated at an interface of the semiconductor substrate 12 through application of an electric field to the interface of the semiconductor substrate 12. This enables the imaging device 100 to suppress occurrence of a dark current at the interface on the light-receiving-side principal surface of the semiconductor substrate 12. The pinning layer 48 is a specific example of a first layer in the technique according to the present disclosure.

Examples of the high dielectric material that may be used to form the pinning layer 48 include aluminum oxide (Al₂O₃), hafnium oxide (HfO₂), zirconium oxide (ZrO₂), titanium oxide (TiO₂), magnesium oxide (MgO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), erbium oxide (Er₂O₃), thulium oxide (Tm₂O₃), ytterbium oxide (Yb₂O₃), lutetium oxide (Lu₂O₃), and yttrium oxide (Y₂O₃).

An interlayer insulating layer 46 including a highly light-transmissive insulating material is provided on a light-receiving-side surface of the pinning layer 48. The interlayer insulating layer 46 may include, for example, an insulating material having a transmittance of about 70% or more for light in the visible light band. Furthermore, in order to suppress reflection of incident light, the interlayer insulating layer 46 may include an insulating material having a smaller refractive index than a refractive index of the semiconductor region 41 and the semiconductor regions 42.

Examples of the insulating material that may be used to form the interlayer insulating layer 46 include silicon oxide (SiO₂), silicon nitride (SiN), silicon oxynitride (SiON), hafnium oxide (HfO₂), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (Pm₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (Ho₂O₃), thulium oxide (Tm₂O₃), ytterbium oxide (Yb₂O₃), lutetium oxide (Lu₂O₃), and yttrium oxide (Y₂O₃).

Light blocking sections 49 that define the pixels 2 are provided along boundary regions of the pixels 2 on a light-receiving-side surface of the interlayer insulating layer 46. Examples of materials that may be used to form the light blocking section 49 include a material that is able to block light, such as tungsten (W), aluminum (Al), or copper (Cu).

A planarizing film 50 is formed across the entire light-receiving-side surfaces of the light blocking sections 49 and the interlayer insulating layer 46. The planarizing film 50 may include, for example, a material such as an organic resin.

Color filter films 51 are provided for each of the pixels 2 on a light-receiving-side surface of the planarizing film 50. The color filter layers 51 may be each formed, for example, by applying a resin containing a pigment or a dye in red, green, or blue onto the light-receiving-side surface of the planarizing film 50. The color filter layers 51 may be arranged, for example, such that the colors red, green, and blue are arranged in the Bayer array or such that the colors red, green, and blue are in another arrangement.

On-chip lenses 52 are provided for each of the pixels 2 on light-receiving-side surfaces of the color filter layers 51. Specifically, the on-chip lenses 52 are provided for each of the pixels 2 as convex lenses that condense incident light on the imaging device 100 in order to cause the light to efficiently enter the photodiodes PD. The on-chip lenses 52 may include, for example, a transparent organic resin such as a styrene-based resin, an acrylic-based resin, a styrene-acrylic copolymer-based resin, or a siloxane-based resin to have a transmittance of 70% or more for light in the visible light band.

As described above, the plurality of pillars 47 arranged at a period smaller than a wavelength of light belonging to the visible light band is provided on the light-receiving-side principal surface, on which light is incident, of the semiconductor substrate 12 of the imaging device 100 according to the present embodiment. As a result, the plurality of pillars 47 configures the uneven structure 45 on the principal surface of the semiconductor substrate 12. The following now describes a specific shape of the uneven structure 45 including the plurality of pillars 47 with reference to FIGS. 3A and 3B. FIG. 3A is a vertical cross-sectional view of a specific shape of the uneven structure 45. FIG. 3B is a graph diagram illustrating a result of simulation of the light reflection-suppressing effect produced by the uneven structure 45.

As illustrated in FIG. 3A, the uneven structure 45 provided on the light-receiving-side principal surface of the semiconductor substrate 12 is formed by arranging the plurality of pillars 47 each having a protruding shape that extends in the thickness direction of the semiconductor substrate 12, at a period smaller than a wavelength of light belonging to the visible light band.

Specifically, the pillar 47 has a tapered shape in which an area of a cross-section thereof taken in an in-plane direction of the semiconductor substrate 12 narrows toward a tip of the pillar 47. The cross-sectional shape of the pillar 47 taken in the in-plane direction of the semiconductor substrate 12 may be, for example, a circular shape, an oval shape, or a polygonal shape having three, four, or five or more sides. Furthermore, the cross-sectional shape of the pillar 47 taken in the in-plane direction of the semiconductor substrate 12 may be the same regardless of the level where the cross-section is taken or may vary depending on the level where the cross-section is taken.

The three-dimensional shape of the pillar 47 may be, for example, a conical shape or a pyramidal shape in which the tip of the pillar 47 has a shape with a vertex. Alternatively, the three-dimensional shape of the pillar 47 may be a shape obtained by changing the shape of the tip of such a conical shape or a pyramidal shape from a shape with a vertex to a hemispherical shape. Furthermore, the three-dimensional shape of the pillar 47 may be a frusto-conical shape or a frusto-pyramidal shape, for example, in which the tip of the pillar 47 forms a flat part.

It is to be noted that the plurality of pillars 47 forming the uneven structure 45 may have similar three-dimensional shapes to one another or may have different three-dimensional shapes from one another.

The uneven structure 45 is formed by two-dimensionally arranging the pillars 47. For example, the uneven structure 45 may be formed by two-dimensionally and periodically arranging the pillars 47 in the in-plane direction of the semiconductor substrate 12 into a square lattice arrangement or a hexagonal close-packed arrangement. Alternatively, the uneven structure 45 may be formed by randomly arranging the pillars 47 in the in-plane direction of the semiconductor substrate 12.

The pillars 47 may be arranged at a period of 200 nm or less, for example. Arranging the pillars 47 at a period in the above-described range enables the uneven structure 45 to suppress occurrence of diffraction of light due to the periodic structure. It is to be noted that the period with which the pillars 47 are arranged may have a lower limit of 20 nm from the viewpoint of a process of forming the pillars 47.

The period with which the pillars 47 are arranged may be defined, for example, as a distance between vertices that are the most protruded at the tips of adjacent pillars 47 or a distance between base points that are the most recessed between adjacent pillars 47.

It should be noted here that each of the pillars 47 forming the uneven structure 45 according to the present embodiment may have an aspect ratio (h/r) of 1 or more, which is determined by dividing a height h of the pillar 47 by a diameter r of a base of the pillar in an arbitrary direction.

In a case where the three-dimensional shape of the pillar 47 is a conical shape, for example, the height h of the pillar 47 may be defined as a distance from an intersection point, between a straight line extending in the thickness direction of the semiconductor substrate 12 from a point (i.e., a vertex) that is the most protruded at the tip of the pillar 47 and a plane including points that are the most recessed in adjacent pillars 47, to the point (i.e., the vertex) that is the most protruded at the tip of the pillar 47.

Furthermore, the diameter r of the base of the pillar 47 in an arbitrary direction may be defined as a diameter, in the arbitrary direction, of a cross-sectional shape of the pillar 47 taken along a plane including points that are the most recessed in adjacent pillars 47. It is to be noted that, in a case where the pillar 47 has a flattened cross-sectional shape such as an oval cross-sectional shape, the above-described diameter in an arbitrary direction may be defined as a diameter along a long axis thereof. Furthermore, in a case where the pillar 47 has a polygonal cross-sectional shape, a diameter of a circumscribed circle of the polygonal shape may be defined as the diameter of the base of the pillar 47 in an arbitrary direction.

In the imaging device 100 according to the present embodiment, the pillar 47 may have an aspect ratio (h/r) of 1 or more as derived in accordance with the above-described definitions. The uneven structure 45 including such pillars 47 is able to further increase a distance, in the thickness direction of the semiconductor substrate 12, for the refractive index to vary for incident light. The uneven structure 45 is therefore able to cause the refractive index for incident light to vary more gently, thus making it possible to further suppress reflection of the incident light.

The following now describes the light reflection-suppressing effect produced by the uneven structure 45 with reference to FIG. 3B.

The graph diagram in FIG. 3B illustrates a result of the simulation of light reflectance on silicon substrates in which an Al₂O₃ film having a thickness of 10 nm, a TaO film having a thickness of 50 nm, and an SiO₂ film having a thickness of 150 nm are stacked in sequence. Specifically, Test Example 1 indicates the light reflectance on a silicon substrate in which the Al₂O₃, TaO, and SiO₂ films are stacked in sequence on a flat surface having no uneven structure 45. Meanwhile, Test Example 2 indicates the light reflectance on a silicon substrate in which the Al₂O₃, TaO, and SiO₂ films are stacked in sequence on a surface having the uneven structure 45 in which the pillars 47 each having a height of 200 nm and a base diameter of 100 nm (aspect ratio: 2) are arranged at a pitch of 200 nm.

According to the graph diagram in FIG. 3B, it is appreciated that Test Example 2 involving the uneven structure 45 is able to significantly reduce the light reflectance at the entire wavelength bands of visible light (e.g., wavelength bands of 350 nm to 800 nm) as compared with Test Example 1 involving no uneven structure 45. That is, it is appreciated that providing the above-described uneven structure 45 on the light incident surface enables the imaging device 100 according to the present embodiment to further suppress reflection of incident light.

Furthermore, each of the pillars 47 forming the uneven structure 45 according to the present embodiment may have a flat part having a diameter of 10 nm or less in an arbitrary direction at the tip of the pillar 47.

In a case where the three-dimensional shape of the pillar 47 is a frusto-conical shape, for example, the tip of the pillar 47 may be an upper base of the frusto-conical shape, forming the flat part. At this time, a diameter of the upper base of the pillar 47 may be defined as the diameter of the flat part in an arbitrary direction. It is to be noted that, in a case where the upper base of the pillar 47 has a flattened shape such as an oval shape, the above-described diameter in an arbitrary direction may be defined as a diameter along a long axis thereof. Furthermore, in a case where the three-dimensional shape of the pillar 47 is a frusto-pyramidal shape, the diameter of the flat part of the pillar 47 in an arbitrary direction may be defined as a diameter of a circumscribed circle of a polygonal shape of the upper base of the pillar 47.

Furthermore, even in a case where the three-dimensional shape of the pillar 47 is a conical shape or a pyramidal shape, it is possible to define the flat part at the tip of the pillar 47 as long as the tip of the pillar 47 has a hemisphere shape and a curvature thereof is extremely large. Specifically, in a case where a surface of the tip of the pillar 47 has no vertex or edge line and where a variation of the pillar 47 in a height direction is about several nm, the surface of the tip of the pillar 47 may be considered to have the flat part.

In the imaging device 100 according to the present embodiment, the pillar 47 may have, at the tip thereof, the flat part having a diameter of 10 nm or less in an arbitrary direction as derived in accordance with the above-described definitions. This enables the uneven structure 45 to further suppress reflection of incident light on the flat part at the tip of the pillar 47. Thus, the uneven structure 45 is able to further suppress re-flection of incident light.

The following describes variations of the specific shape of the uneven structure 45 with reference to FIGS. 4A to 4C. FIGS. 4A to 4C are vertical cross-sectional views illustrating variations of the specific shape of the uneven structure 45.

For example, as illustrated in FIG. 4A, an uneven structure 45A may be formed by arranging the pillars 47 each having a shape with a vertex at intervals to provide flat parts between the pillars 47. In such a case, an arrangement period p of the pillars 47 may be defined, for example, as a distance between vertices that are the most protruded at the tips of adjacent pillars 47. Furthermore, the diameter r of the base of the pillar 47 in an arbitrary direction may be defined as a diameter, in the arbitrary direction, of a cross-section of the pillar 47 taken along a plane including inflection points at which a side of the pillar 47 rises from the principal surface of the semiconductor substrate 12. Furthermore, the height h of the pillar 47 may be defined as a distance from a plane including the flat part between adjacent pillars 47 to the vertex of the pillar 47.

For example, as illustrated in FIG. 4B, an uneven structure 45B may be formed by arranging the pillars 47, each of which has a frustum shape, adjacently to provide no flat part between the pillars 47. In such a case, the arrangement period p of the pillars 47 may be defined, for example, as a distance between base points that are the most recessed between the adjacent pillars 47. Furthermore, the diameter r of the flat part at the tip of the pillar 47 in an arbitrary direction may be defined as a diameter, in the arbitrary direction, of the upper base of the frusto-conical shape of the pillar 47. Furthermore, the height h of the pillar 47 may be defined as a distance from a plane including points that are the most recessed between adjacent pillars 47 to the upper base of the pillar 47.

For example, as illustrated in FIG. 4C, an uneven structure 45C may be formed by arranging the pillars 47, each of which has a frustum shape, at intervals to provide a flat part between the pillars 47. In such a case, the arrangement period p of the pillars 47 may be defined, for example, as a distance between centers of gravity of the flat parts at the tips of adjacent pillars 47. Furthermore, the diameter r of the base of the pillar 47 in an arbitrary direction may be defined as a diameter, in the arbitrary direction, of a cross-section of the pillar 47 taken along a plane including inflection points at which a side of the pillar 47 arises from the principal surface of the semiconductor substrate 12. Furthermore, the height h of the pillar 47 may be defined as a distance from a plane including the flat parts between adjacent pillars 47 to the upper base of the pillar 47.

As described above, in the imaging device 100 according to the present embodiment, the light-receiving-side principal surface of the semiconductor substrate 12 in which the photodiodes PD serving as photoelectric conversion sections are provided includes thereon the uneven structure 45 at a period smaller than a wavelength of light belonging to the visible light band. This enables the imaging device 100 according to the present embodiment to suppress reflection of incident light on the light-receiving-side principal surface of the semiconductor substrate 12, thus making it possible to suppress flare or ghost in a captured image.

### 2.2. Modification Example

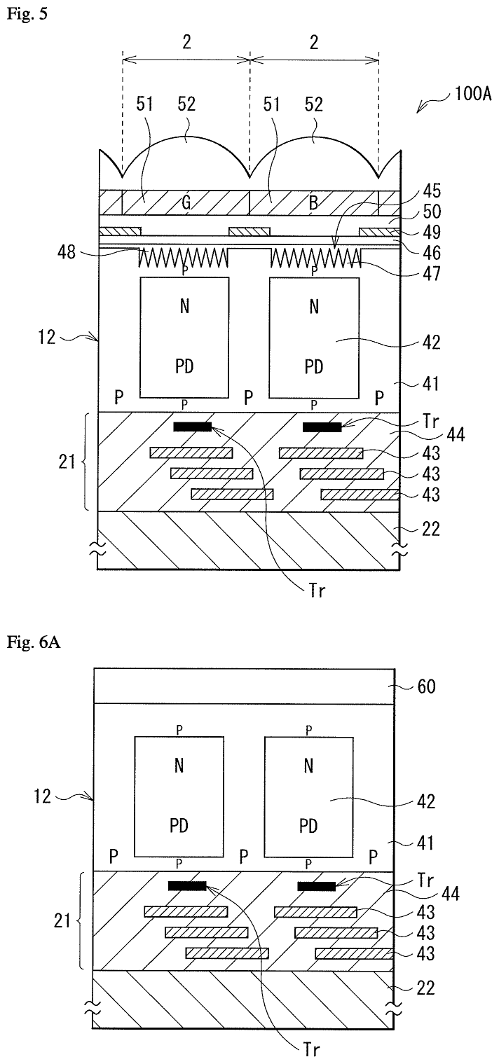

The following describes a modification example of the imaging device 100 according to the present embodiment with reference to FIG. 5. FIG. 5 is a vertical cross-sectional view of a configuration of the pixels 2 in an imaging device 100A according to the present modification example.

As illustrated in FIG. 5, in the imaging device 100A according to the present modification example, the uneven structure 45 on the light-receiving-side principal surface of the semiconductor substrate 12 may be provided in regions corresponding to the photodiodes PD.

Specifically, the uneven structure 45 may be provided in regions corresponding to upper surfaces of the photodiodes PD provided for the respective pixels 2. That is, the light-receiving-side principal surface of the semiconductor substrate 12 may be provided to allow the regions corresponding to the pixels 2 to have the uneven structure 45 and regions corresponding to boundaries between the pixels 2 to be flat.

In the imaging device 100A according to the present modification example, the regions, of the light-receiving-side principal surface of the semiconductor substrate 12, that correspond to the pixels 2 and receive incident light condensed by the on-chip lenses 52 are provided with the uneven structure 45. This enables the imaging device 100A according to the present modification example to suppress reflection of incident light on the light-receiving-side principal surface of the semiconductor substrate 12 more efficiently.

Furthermore, in the imaging device 100A according to the present modification example, providing the uneven structure 45 in the regions corresponding to the pixels 2, of the light-receiving-side principal surface of the semiconductor substrate 12, and providing the flat part in the regions corresponding to the boundaries between the pixels 2, of such a principal surface, make it possible to suppress occurrence of diffraction of light due to the periodic structure of the uneven structure 45.

### 2.3. Formation Method of Uneven Structure

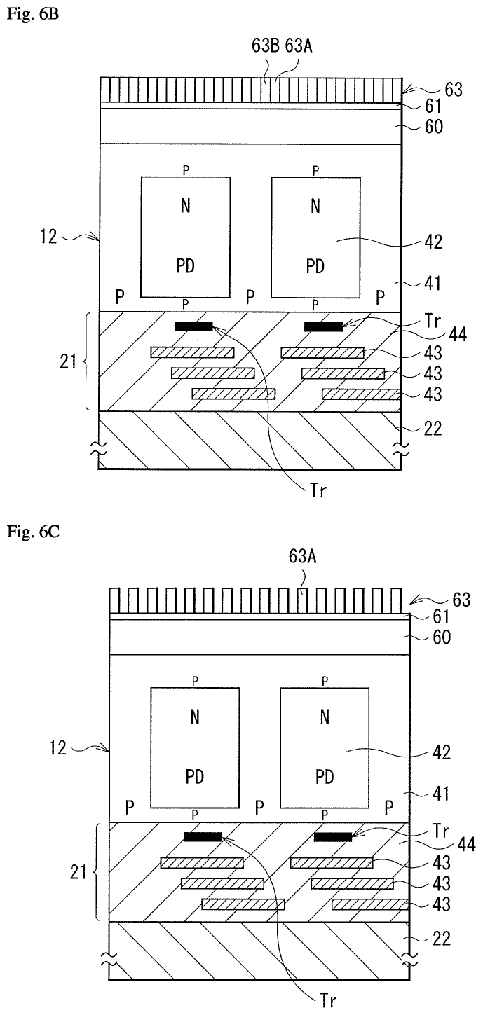

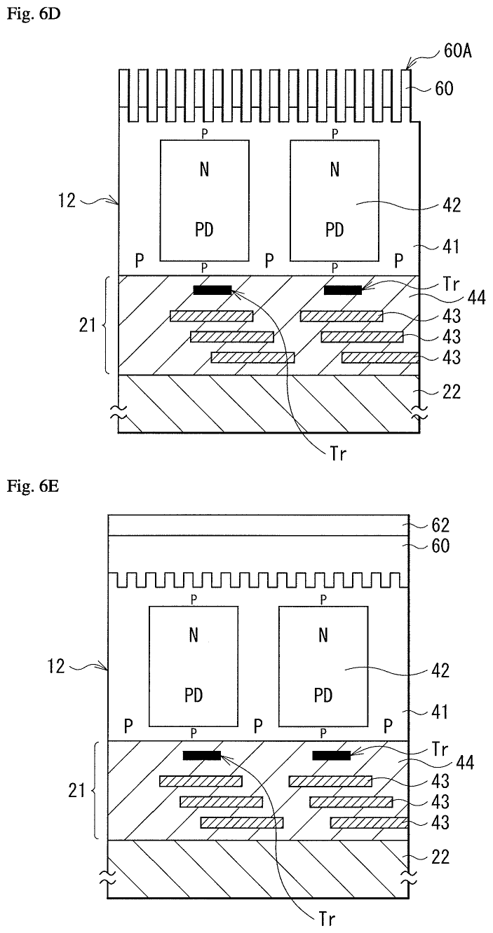

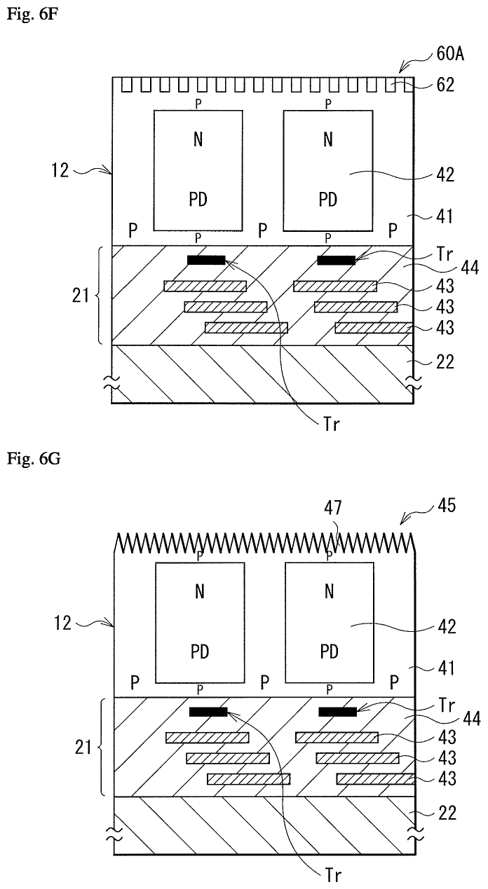

The following describes a formation method of the uneven structure 45 in the imaging device 100 according to the present embodiment with reference to FIGS. 6A to 6G. FIGS. 6A to 6G are vertical cross-sectional views each describing one of steps of forming the uneven structure 45 in the imaging device 100 according to the present embodiment.

First, a laminate is formed by stacking the semiconductor substrate 12, the multi-layer wiring layer 21, and the support substrate 22 by a known method. Furthermore, the semiconductor regions 42 of the second electrically-conductive type are formed inside the semiconductor substrate 12. This allows the photodiodes PD to be formed inside the semiconductor substrate 12.

Next, as illustrated in FIG. 6A, a hardmask 60 containing silicon oxide (SiO₂) is placed on a surface, of the semiconductor substrate 12, opposite to a surface on which the multi-layer wiring layer 21 is stacked.

Subsequently, as illustrated in FIG. 6B, a resist layer 63 is formed on the hardmask 60 with an intermediate layer 61 therebetween. The intermediate layer 61 is, for example, a layer containing silicon nitride (SiN), and is provided to increase adhesion of the resist layer 63 to the hardmask 60.

The resist layer 63 may be, for example, a resin layer containing a self-assembled block copolymer such as polystyrene-polymethylmethacrylate (PS-PMMA). The self-assembled block copolymer is a macromolecule obtained through chemical bonding of two polymers that are less compatible with each other. The self-assembled block copolymer is able to spontaneously form a regular periodic structure through phase separation in regions at a micro level of about several nm to several tens of nm due to repulsion between the less compatible polymers.

For example, the self-assembled block copolymer is able to form a unique periodic structure such as a spherical structure (also referred to as a sphere structure), a cylindrical structure (also referred to as a cylinder structure), or a layered structure (also referred to as a lamella structure) depending on a composition ratio between the two chemically bonded polymers. Furthermore, it is possible to control the repetitive size of the periodic structure depending on the molecular weights of the two chemically bonded polymers in the self-assembled block copolymer.

It is therefore possible to form the resist layer 63 having a periodic structure at a period smaller than a wavelength of light belonging to the visible light band on the intermediate layer 61 by appropriately controlling the molecular structure of the self-assembled block copolymer. Specifically, it is possible to form the resist layer 63 in which second phases 63B including spheres or cylinders are periodically arranged inside a first phase 63A by applying the self-assembled block copolymer having a desired molecular structure onto the intermediate layer 61 and thereafter performing a heat treatment on the resultant film.

Subsequently, as illustrated in FIG. 6C, a pattern is formed in the resist layer 63 by removing one of the polymer phases from the resist layer 63. Specifically, a pattern of holes in a periodic arrangement is formed in the resist layer 63 by removing the second phase 63B from the resist layer 63 by a process such as wet etching.

Next, as illustrated in FIG. 6D, dry etching is performed on the hardmask 60 and the semiconductor substrate 12 using the resist layer 63 with the formed hole pattern as a mask. Specifically, the resist layer 63 and the intermediate layer 61 are removed by a process such as dry etching. Furthermore, regions, of the hardmask 60 and the semiconductor substrate 12, that correspond to the holes periodically formed in the resist layer 63 are removed. This allows for formation of apertures 60A corresponding to the holes periodically formed in the resist layer 63 in the hardmask 60 and the semiconductor substrate 12.

Subsequently, as illustrated in FIG. 6E, a hardmask 62 containing silicon oxide (SiO₂) is further placed on the semiconductor substrate 12 and the hardmask 60 to fill the apertures 60A formed in the hardmask 60 and the semiconductor substrate 12.

Next, as illustrated in FIG. 6F, the hardmasks 60 and 62 are uniformly removed by a process such as dry etching until the semiconductor substrate 12 is exposed. This allows for formation of a structure in which the apertures 60A in a periodic arrangement are filled with the hardmask 62 on the principal surface of the exposed semiconductor substrate 12.

Thereafter, as illustrated in FIG. 6G, dry etching is performed on the semiconductor substrate 12 using the hardmask 62 filling the apertures 60A as a mask. As a result, the semiconductor substrate 12 is etched except regions corresponding to the apertures 60A filled with the hardmask 62, leaving the regions of the semiconductor substrate 12 corresponding to the apertures 60A as shape of protrusions. This makes it possible to form the pillars 47 in the shape of protrusions in a periodic arrangement and the uneven structure 45 including the pillars 47 on the principal surface of the semiconductor substrate 12.

The above-described steps allow the uneven structure 45 to be formed in the imaging device 100 according to the present embodiment. The above-described steps allow the uneven structure 45 at a period smaller than a wavelength of light belonging to the visible light band to be formed more easily with the use of the self-assembled block copolymer.

Furthermore, the above-described steps allow the uneven structure 45 to be formed in the semiconductor substrate 12 as a pillar pattern by reversing the tone of the hole pattern formed in the resist layer 63 containing the self-assembled block copolymer. Thus, in the imaging device 100 according to the present embodiment, it is possible to easily form a steep pillar 47 that satisfies at least one of conditions: an aspect ratio of 1 or more, which is determined by dividing the height of the pillar 47 by the diameter of the base of the pillar 47; or a diameter of 10 nm or less, which is the diameter of the flat part at the tip of the pillar 47.

### 3. Second Embodiment

### 3.1. Configuration of Pixels

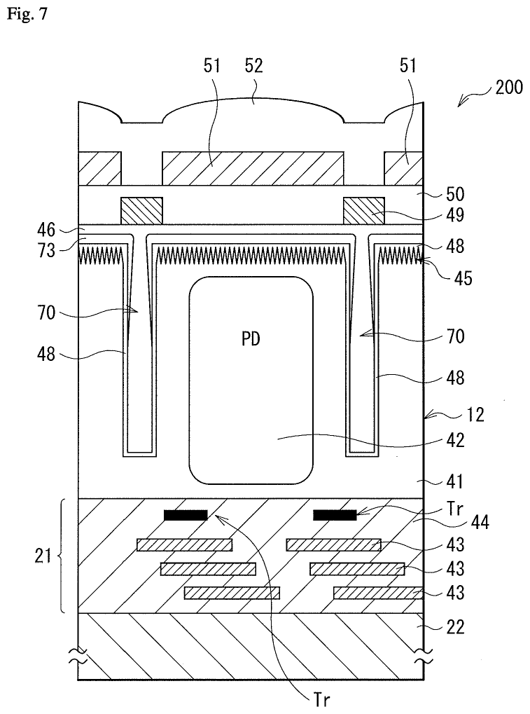

The following describes a configuration of the pixels 2 in an imaging device 200 according to a second embodiment of the present disclosure with reference to FIG. 7. FIG. 7 is a vertical cross-sectional view of the configuration of the pixels 2 in the imaging device 200 according to the present embodiment.

As illustrated in FIG. 7, the imaging device 200 may include, for example, the semiconductor substrate 12, the multi-layer wiring layer 21, and the support substrate 22.

The semiconductor substrate 12 is a substrate including a semiconductor such as silicon. The semiconductor substrate 12 may include, for example, inside the semiconductor region 41 of the first electrically-conductive type (e.g., p-type), the semiconductor region 42 of the second electrically-conductive type (e.g., n-type) for each of the pixels 2. Thus, the photodiodes PD that function as photoelectric conversion sections are provided in the semiconductor substrate 12 for each of the pixels 2.

Furthermore, the light-receiving-side principal surface, on which light is incident, of the semiconductor substrate 12 includes, thereon, the plurality of pillars 47 arranged at a period smaller than a wavelength of light belonging to the visible light band. The plurality of pillars 47 forms the uneven structure 45 that functions as the moth-eye structure, thereby making it possible to suppress reflection of incident light on the light-receiving-side principal surface of the semiconductor substrate 12. The specific shape of the uneven structure 45 is as described in association with the imaging device 100 according to the first embodiment, and therefore description thereof is omitted here.

The imaging device 200 according to the present embodiment further includes a pixel separation layer 70 between the pixels 2 in the semiconductor substrate 12. The pixel separation layer 70 is provided between the adjacent pixels 2 to extend in the thickness direction of the semiconductor substrate 12 from the light-receiving-side principal surface to the opposite principal surface of the semiconductor substrate 12.

The pixel separation layer 70 may include an insulating material in order to electrically separate the photodiodes PD of the pixels 2 from each other. For example, the pixel separation layer 70 may include the same insulating material as that for the interlayer insulating layer 46. This allows the pixel separation layer 70 to be formed at the same time as the interlayer insulating layer 46, thus making it possible to simplify production steps of the imaging device 200.

The pinning layer 48 is provided on the light-receiving-side surface of the semiconductor substrate 12 to fill the uneven portion of the uneven structure 45. The pinning layer 48 includes a high dielectric material having a negative fixed charge, and provides a hole accumulation region at an interface on the semiconductor substrate 12. This enables the imaging device 200 to suppress occurrence of a dark current on the light-receiving-side principal surface of the semiconductor substrate 12. It is to be noted that the pinning layer 48 is a specific example of the first layer in the technique according to the present disclosure, and may include any of the various high dielectric materials described in the first embodiment.

Furthermore, the pinning layer 48 may be provided to cover the periphery of the pixel separation layer 70. The pinning layer 48 provides the hole accumulation region at the interface between the semiconductor substrate 12 and the pixel separation layer 70, thereby making it possible to suppress occurrence of a dark current at the interface between the semiconductor substrate 12 and the pixel separation layer 70.

An antireflection layer 73 is provided on the light-receiving-side surface of the pinning layer 48. The antireflection layer 73 includes an insulating material having a smaller refractive index than a refractive index of the high dielectric material of the pinning layer 48. This enables the antireflection layer 73 to prevent reflection of light entering the antireflection layer 73 and the pinning layer 48 in a direction from the on-chip lens 52. The antireflection layer 73 may include, for example, tantalum oxide (Ta₂O₅). It is to be noted that the antireflection layer 73 is a specific example of a second layer in the technique according to the present disclosure.

The interlayer insulating layer 46 is provided on a light-receiving-side surface of the antireflection layer 73. The interlayer insulating layer 46 may include the highly light-transmissive insulating material (e.g., having a transmittance of about 70% or more for light of the visible light band) described above in the first embodiment.

Furthermore, the interlayer insulating layer 46 may be continuous with the pixel separation layer 70. Specifically, the interlayer insulating layer 46 may be formed using the same insulating material as that for the pixel separation layer 70. It is sufficient for the interlayer insulating layer 46 and the pixel separation layer 70 to have at least insulation properties. It is therefore possible to form the interlayer insulating layer 46 and the pixel separation layer 70 using the same insulating material in a case where optical properties thereof are not taken into consideration.

It is to be noted that configurations of the multi-layer wiring layer 21, the support substrate 22, the light blocking section 49, the planarizing film 50, the color filter layers 51, and the on-chip lens 52 are substantially similar to the configurations described in association with the imaging device 100 according to the first embodiment, and therefore description thereof is omitted here.

The imaging device 200 according to the present embodiment includes the pixel separation layer 70 between the pixels 2 as well as the uneven structure 45 on the light-receiving-side principal surface of the semiconductor substrate 12. This enables the imaging device 200 according to the present embodiment to suppress incidence of scattered light due to the uneven structure 45 into adjacent pixels 2 as stray light. Thus, the imaging device 200 according to the present embodiment is able to suppress re-flection of incident light on the light-receiving-side principal surface of the semiconductor substrate 12 and to suppress incidence of scattered light or the like into the adjacent pixels 2. Thus, it is possible for the imaging device 200 according to the present embodiment to suppress mixing of colors between the pixels 2 as well as to suppress flare or ghost.

### 3.2. Modification Examples

### First Modification Example

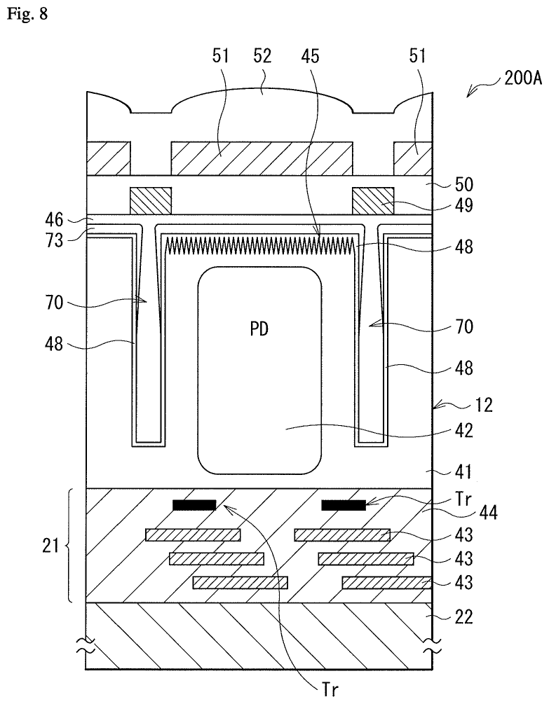

The following describes a first modification example of the imaging device 200 according to the present embodiment with reference to FIG. 8. FIG. 8 is a vertical cross-sectional view of a configuration of the pixels 2 in an imaging device 200A according to the first modification example of the present embodiment.

As illustrated in FIG. 8, in the imaging device 200A according to the first modification example, the uneven structure 45 on the light-receiving-side principal surface of the semiconductor substrate 12 may be provided in regions corresponding to several photodiodes PD.

Specifically, the uneven structure 45 may be provided in a region corresponding to a predetermined pixel 2, of the light-receiving-side principal surface of the semiconductor substrate 12. That is, the light-receiving-side principal surface of the semiconductor substrate 12 may be provided to allow the region corresponding to the predetermined pixel 2 to have the uneven structure 45 and regions corresponding to pixels other than the predetermined pixel 2 to be flat.

In the imaging device 200A according to the present modification example, providing the uneven structure 45 in the region corresponding to the predetermined pixel 2, of the light-receiving-side principal surface of the semiconductor substrate 12, and providing the flat part in the regions corresponding to the pixels other than the predetermined pixel 2, of such a principal surface, make it possible suppress occurrence of diffraction of light due to the periodic structure of the uneven structure 45.

### Second Modification Example

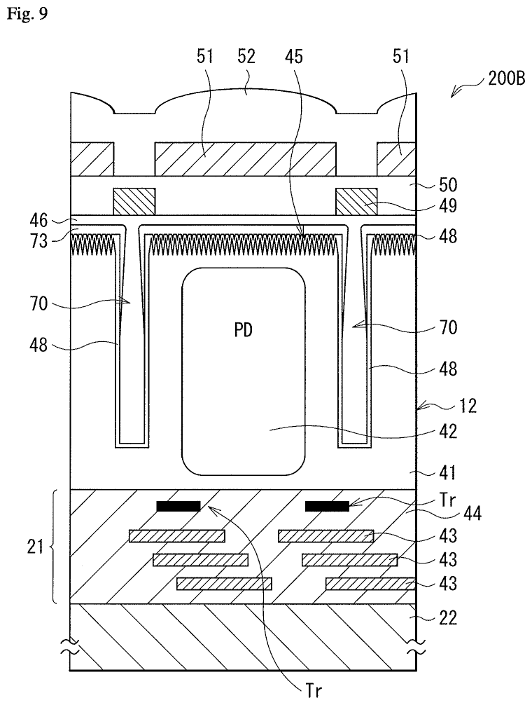

The following describes a second modification example of the imaging device 200 according to the present embodiment with reference to FIG. 9. FIG. 9 is a vertical cross-sectional view of a configuration of the pixels 2 in an imaging device 200B according to the second modification example of the present embodiment.

As illustrated in FIG. 9, in the imaging device 200B according to the second modification example, the pinning layer 48 may be provided along the uneven portion of the uneven structure 45.

Specifically, the pinning layer 48 may be provided as a thin film layer having any shape conforming to the uneven portion of the uneven structure 45 to cover a surface of the uneven structure 45. In such a case, the antireflection layer 73 to be provided on the pinning layer 48 may be provided to fill the uneven portion of the uneven structure 45 and the pinning layer 48.

In the imaging device 200B according to the second modification example, the pinning layer 48 and the antireflection layer 73 are provided between the pillars 47 of the uneven structure 45. This enables the imaging device 200B according to the second modification example to have a refractive index that varies more gradually from the antireflection layer 73 to the semiconductor substrate 12 in the thickness direction of the semiconductor substrate 12. This makes it possible for the imaging device 200B according to the second modification example to further suppress reflection of incident light inside the imaging device 200B.

### Third Modification Example

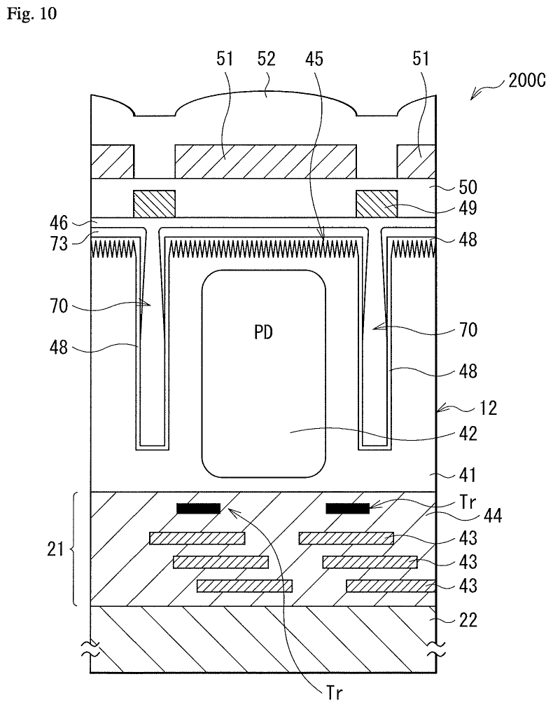

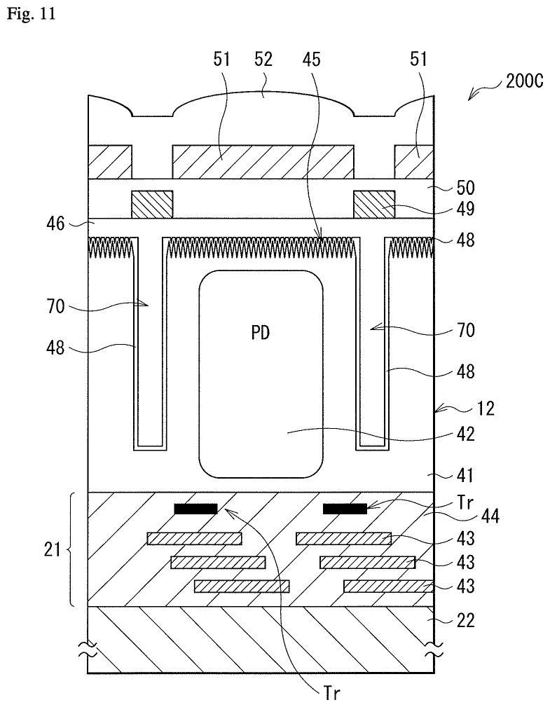

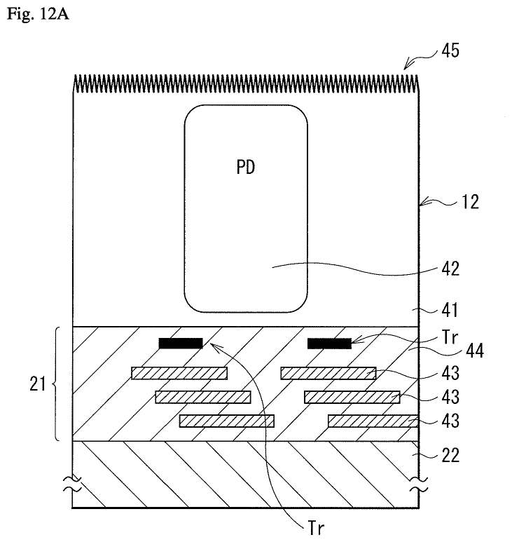

The following describes a third modification example of the imaging device 200 according to the present embodiment with reference to FIGS. 10 and 11. FIGS. 10 and 11 are each a vertical cross-sectional view of a configuration of the pixels 2 in an imaging device 200C according to the third modification example of the present embodiment.

As illustrated in FIGS. 10 and 11, the imaging device 200C according to the third modification example may include no antireflection layer 73. That is, in the imaging device 200C according to the third modification example, the pinning layer 48 is provided on the uneven structure 45, and the interlayer insulating layer 46 is provided directly on the pinning layer 48. It is to be noted that the pinning layer 48 may be provided along the uneven portion of the uneven structure 45 as illustrated in FIG. 10, or may be provided to fill the uneven portion of the uneven structure 45 as illustrated in FIG. 11.

The imaging device 200C according to the third modification example suppress re-flection of incident light by means of the uneven structure 45, and may omit the antireflection layer 73. In such a case, the imaging device 200C is able to prevent the antireflection layer 73 provided on the uneven structure 45 from narrowing apertures having a trench structure provided for formation of the pixel separation layer 70.

In the imaging device 200C according to the third modification example, therefore, it is possible to form the pixel separation layer 70 more easily inside the trench structure formed in the thickness direction of the semiconductor substrate 12.

### 3.3. Manufacturing Method

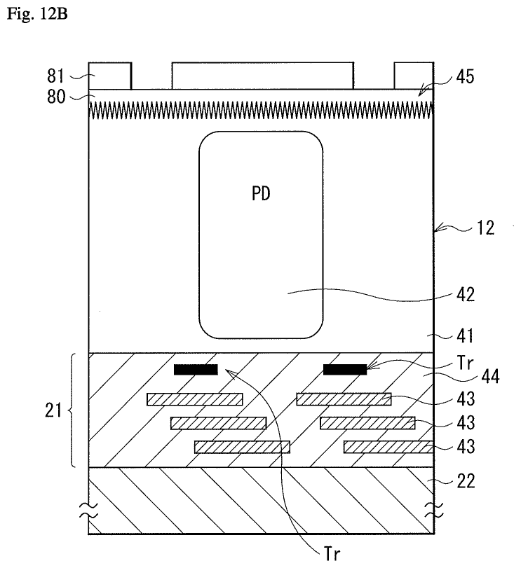

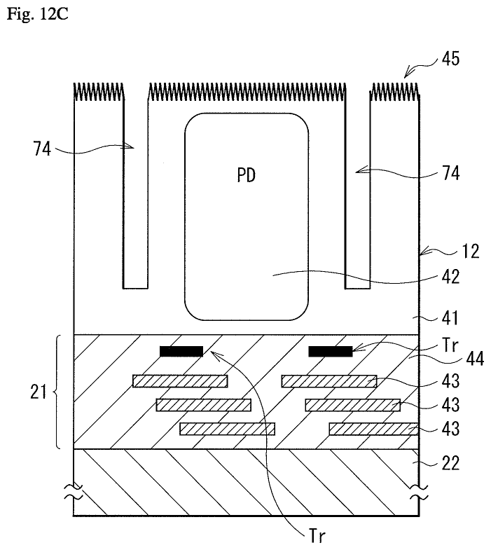

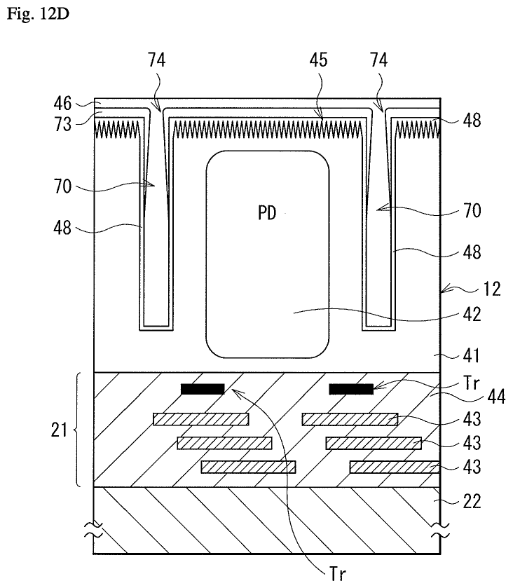

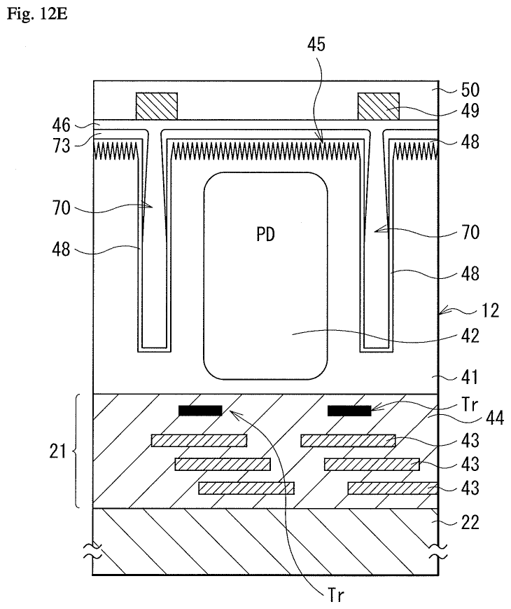

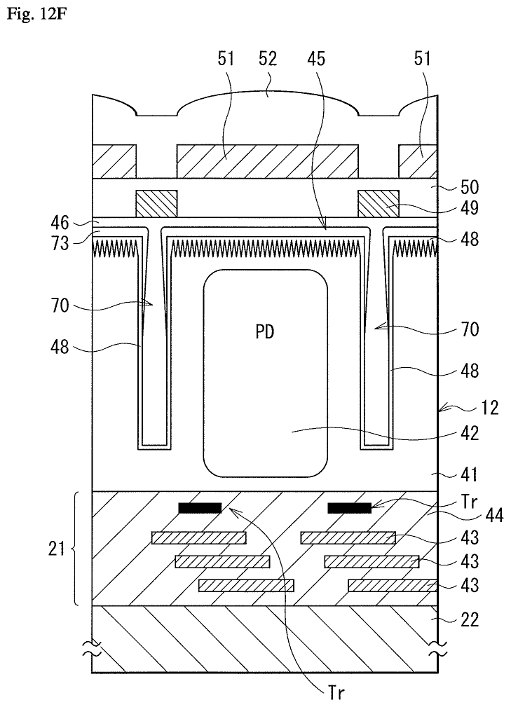

The following describes a manufacturing method for the imaging device 200 according to the present embodiment with reference to FIGS. 12A to 12F. FIGS. 12A to 12F are each a vertical cross-sectional view describing one of steps of manufacturing the imaging device 200 according to the present embodiment.

First, as illustrated in FIG. 12A, the plurality of pillars 47 in a periodic arrangement is formed on the light-receiving-side principal surface of the semiconductor substrate 12 in a method similar to that described in the first embodiment. This allows the uneven structure 45 to be provided on the light-receiving-side principal surface of the semiconductor substrate 12.

Next, as illustrated in FIG. 12B, a protective film 80 containing a material such as an organic resin is applied to protect the uneven structure 45 provided on the light-receiving-side principal surface of the semiconductor substrate 12, and then a photoresist 81 is further applied onto the protective film 80. Thereafter, the photoresist 81 is patterned by a process such as photolithography to open parts thereof corresponding to regions in which the pixel separation layer 70 is to be formed.

Subsequently, as illustrated in FIG. 12C, anisotropic dry etching is performed using the patterned photoresist 81 as a mask to thereby form the trench structure 74 in which the pixel separation layer 70 is to be formed later. Thereafter, the remaining photoresist 81 and the protective film 80 are removed.

Next, as illustrated in FIG. 12D, the pinning layer 48 is formed along the shapes of the uneven structure 45 and the trench structure 74. Specifically, the pinning layer 48 is deposited in a uniform thickness on the uneven structure 45 and inside the trench structure 74 along the uneven portion of the exposed surface of the semiconductor substrate 12. Subsequently, the antireflection layer 73 is formed on the uneven structure 45, on which the pinning layer 48 is formed, to fill the recess shape of the uneven structure 45.

Furthermore, the interlayer insulating layer 46 is formed on the antireflection layer 73. Providing the interlayer insulating layer 46 to fill the inside of the trench structure 74 makes it possible to form the pixel separation layer 70 inside the trench structure 74.

Subsequently, as illustrated in FIG. 12E, the light blocking sections 49 are formed in regions corresponding to the boundaries between the pixels 2 by a process such as photolithography, and subsequently the planarizing film 50 is formed to cover the light blocking sections 49.

Next, as illustrated in FIG. 12F, the color filter layers 51 and the on-chip lenses 52 are formed in sequence on the planarizing film 50. This allows the imaging device 200 according to the present embodiment to be manufactured. It is possible for the imaging device 200 according to the present embodiment to suppress mixing of colors between the pixels 2 as well as to suppress flare or ghost.

### 4. Third Embodiment

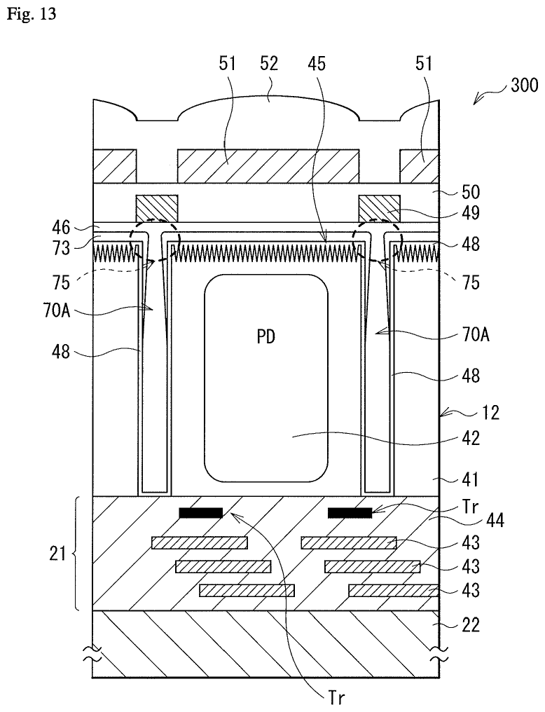

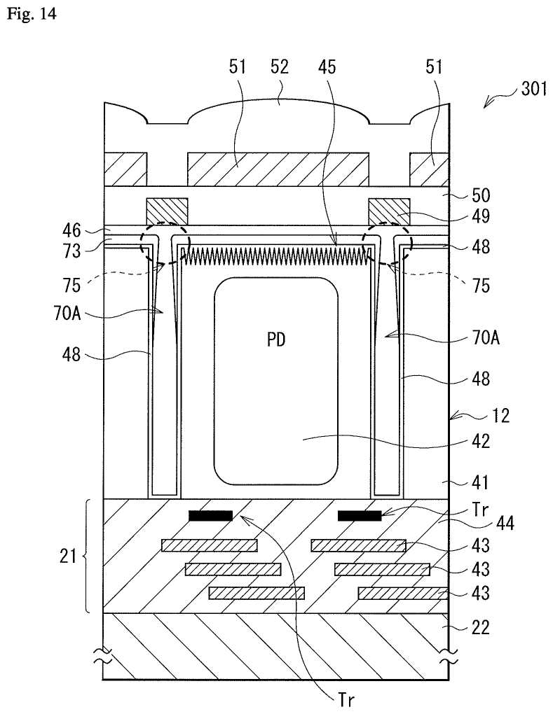

The following describes a configuration of the pixels 2 in an imaging device according to a third embodiment of the present disclosure with reference to FIGS. 13 and 14. FIG. 13 is a vertical cross-sectional view of an example of the configuration of the pixels 2 in the imaging device according to the present embodiment. FIG. 14 is a vertical cross-sectional view of a modification example of the configuration of the pixels 2 in the imaging device according to the present embodiment.

As illustrated in FIG. 13, an imaging device 300 according to the third embodiment is different from the imaging device 200 according to the second embodiment in that the imaging device 300 is provided with pixel separation layers 70A penetrating the semiconductor substrate 12. Providing the pixel separation layers 70A to penetrate the semiconductor substrate 12 enable the imaging device 300 according to the third embodiment to electrically and optically separate the adjacent pixels 2 from one another more reliably.

Such pixel separation layers 70A may be provided, for example, by forming apertures penetrating the semiconductor substrate 12 by etching from the light-receiving-side principal surface of the semiconductor substrate 12, and by filling the resultant apertures with an insulating material.

It is to be noted that the aperture for the pixel separation layer 70A is provided before the formation of the uneven structure 45. This enables the imaging device 300 according to the third embodiment to avoid a situation in which the uneven structure 45 is damaged by the etching performed to provide the aperture for the pixel separation layer 70A. In such a case, for overlay accuracy in lithography or etching, the uneven structure 45 is not formed in a vicinity section 75 of the pixel separation layer 70A, and the vicinity section 75 of the pixel separation layer 70A is flat.

Furthermore, in an imaging device 301 according to the third embodiment, the uneven structures 45 on the light-receiving-side principal surface of the semiconductor substrate 12 may be provided in regions corresponding to several photodiodes PD as illustrated in FIG. 14.

Specifically, the uneven structure 45 may be provided in a region corresponding to a predetermined pixel 2 of the light-receiving-side principal surface of the semiconductor substrate 12. That is, the light-receiving-side principal surface of the semiconductor substrate 12 may be provided to allow the region corresponding to the predetermined pixel 2 to have the uneven structure 45 and regions corresponding to the pixels other than the predetermined pixel 2 to be flat. Providing the uneven structure 45 in the region corresponding to the predetermined pixel 2, of the light-receiving-side principal surface of the semiconductor substrate 12, makes it possible for the imaging device 301 to suppress occurrence of diffraction of light due to the periodic structure of the uneven structure 45.

### 5. Fourth Embodiment

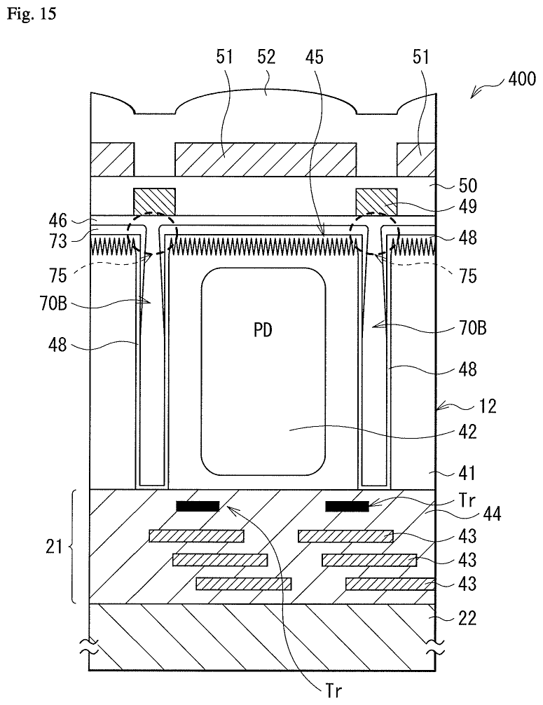

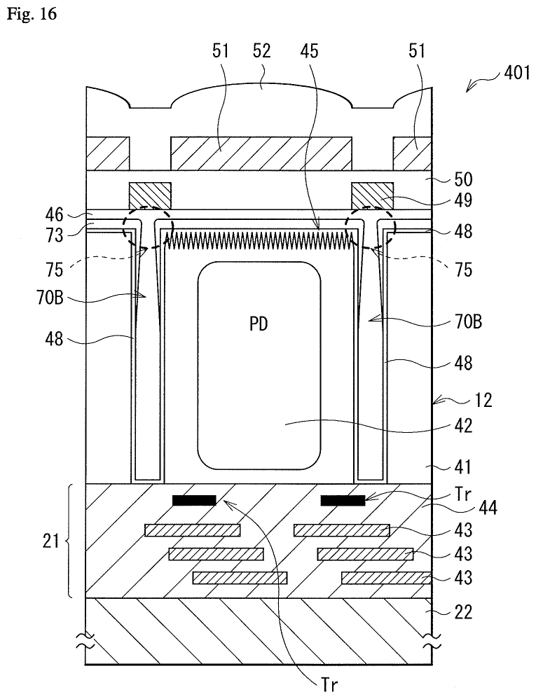

The following describes a configuration of the pixels 2 in an imaging device according to a fourth embodiment of the present disclosure with reference to FIGS. 15 and 16. FIG. 15 is a vertical cross-sectional view of an example of the configuration of the pixels 2 in the imaging device according to the present embodiment. FIG. 16 is a vertical cross-sectional view of a modification example of the configuration of the pixels 2 in the imaging device according to the present embodiment.

As illustrated in FIG. 15, an imaging device 400 according to the fourth embodiment is different from the imaging device 200 according to the second embodiment in that the imaging device 400 is provided with pixel separation layers 70B penetrating the semiconductor substrate 12. Providing the pixel separation layers 70B to penetrate the semiconductor substrate 12 enable the imaging device 400 according to the fourth embodiment to electrically and optically separate the pixels 2 from one another more reliably.

Such pixel separation layers 70B may be provided, for example, by forming apertures penetrating the semiconductor substrate 12 by etching from the principal surface that is opposite to the light-receiving-side principal surface of the semiconductor substrate 12 and by filling the resultant apertures with an insulating material.

It is to be noted that the aperture for the pixel separation layer 70B is formed from the principal surface that is opposite to the light-receiving-side principal surface of the semiconductor substrate 12, and thus the apertures may be provided either before or after the formation of the uneven structure 45. In a case where the aperture for the pixel separation layer 70B is formed after the formation of the uneven structure 45, therefore, the uneven structure 45 is formed at the vicinity section 75 of the pixel separation layer 70B. Meanwhile, in a case where the aperture for the pixel separation layer 70B is formed before the formation of the uneven structure 45, the vicinity section 75 of the pixel separation layer 70B is flat without formation of the uneven structure 45.

Furthermore, in an imaging device 401 according to the fourth embodiment, the uneven structure 45 on the light-receiving-side principal surface of the semiconductor substrate 12 may be provided in regions corresponding to several photodiodes PD as illustrated in FIG. 16.

Specifically, the uneven structure 45 may be provided in a region corresponding to a predetermined pixel 2 of the light-receiving-side principal surface of the semiconductor substrate 12. That is, the light-receiving-side principal surface of the semiconductor substrate 12 may be provided to allow the region corresponding to the predetermined pixel 2 to have the uneven structure 45 and regions corresponding to the pixels other than the predetermined pixel 2 to be flat. Providing the uneven structure 45 in the region corresponding to the predetermined pixel 2, of the light-receiving-side principal surface of the semiconductor substrate 12 makes it possible for the imaging device 401 to suppress occurrence of diffraction of light due to the periodic structure of the uneven structure 45.

### 6. Fifth Embodiment

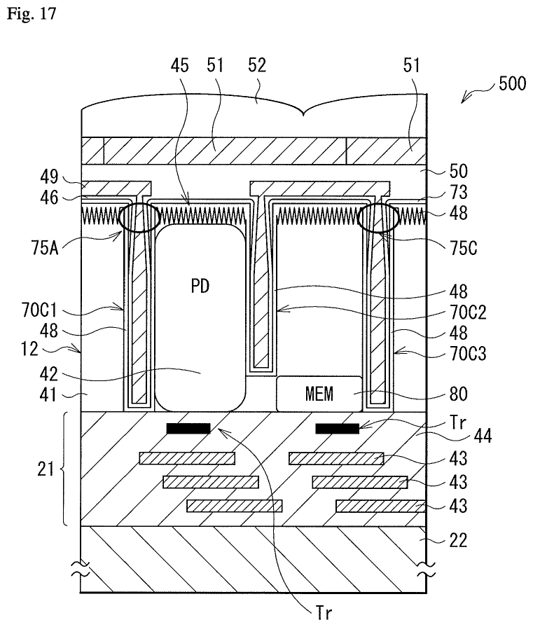

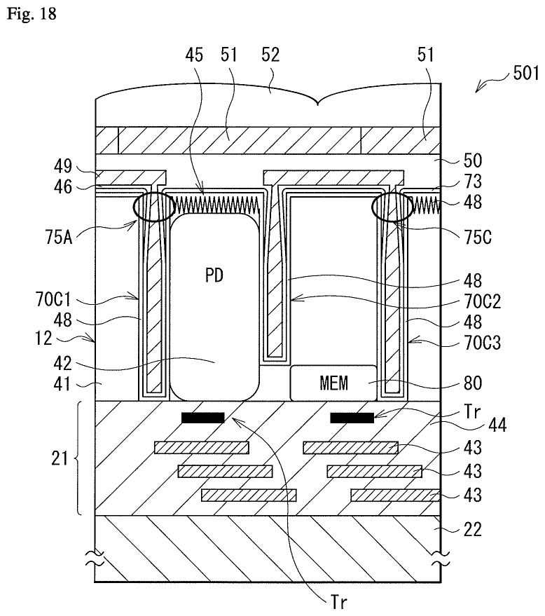

The following describes a configuration of the pixels 2 in an imaging device according to a fifth embodiment of the present disclosure with reference to FIGS. 17 and 18. FIG. 17 is a vertical cross-sectional view of an example of the configuration of the pixels 2 in the imaging device according to the present embodiment. FIG. 18 is a vertical cross-sectional view of a modification example of the configuration of the pixels 2 in the imaging device according to the present embodiment.

As illustrated in FIG. 17, an imaging device 500 according to the fifth embodiment is different from the imaging device 200 according to the second embodiment in that the imaging device 500 further includes a memory region MEM that holds a charge generated through photoelectric conversion by the photodiode PD.

The memory region MEM is a semiconductor region of the second electrically-conductive type (e.g., n-type), and is provided to achieve a global shuttering function in the imaging device 500. The memory region MEM holds charges accumulated at the same timing in respective photodiodes PD of the pixels 2 until charges are read out in the respective pixels 2.

Furthermore, in order not to generate a new charge, a light-receiving side of the memory region MEM is covered with a light blocking member. Specifically, the memory region MEM is covered with pixel separation layers 70C2 and 70C3 and the light blocking section 49, all of which include the light blocking member.

The pixel separation layers 70C1, 70C2, and 70C3 electrically and optically separate regions of the semiconductor substrate 12 from one another. The pixel separation layers 70C1, 70C2, and 70C3 are obtained by coating a light blocking material containing a metal, an alloy, or a metal compound with an insulating material. For example, the pixel separation layers 70C1, 70C2, and 70C3 may be obtained by coating a laminate of TiAl and Al, a laminate of TiN, Co, and Al, or a laminate of TiN and W with an insulating material similar to that for the interlayer insulating layer 46.

Specifically, the pixel separation layer 70C1 penetrate the semiconductor substrate 12, and electrically or optically separate the adjacent pixels 2 from one another. The pixel separation layer 70C2 extends from the light-receiving-side principal surface of the semiconductor substrate 12 in the thickness direction of the semiconductor substrate 12, and blocks, together with the light blocking section 49 and the pixel separation layer 70C3, light entering the memory region MEM. The pixel separation layer 70C3 penetrates the semiconductor substrate 12, electrically or optically separates the adjacent pixels 2 from one another, and blocks, together with the light blocking section 49 and the pixel separation layer 70C2, light entering the memory region MEM.

The pixel separation layers 70C1 and 70C3 penetrating the semiconductor substrate 12 may be provided, for example, by forming apertures penetrating the semiconductor substrate 12 by etching from the light-receiving-side principal surface of the semiconductor substrate 12, and by filling the resultant apertures with an insulating material and a light blocking material. At this time, the apertures for the pixel separation layers 70C1 and 70C3 are provided before the formation of the uneven structure 45 in order to avoid a situation in which the uneven structure 45 is damaged by prolonged etching. In such a case, the uneven structure 45 is not formed at the vicinity sections 75 of the pixel separation layers 70C1 and 70C3, and the vicinity sections 75 of the pixel separation layers 70C1 and 70C3 are flat.

Furthermore, in an imaging device 501 according to the fifth embodiment, the uneven structure 45 on the light-receiving-side principal surface of the semiconductor substrate 12 may be provided only in regions corresponding to the photodiodes PD as illustrated in FIG. 18.

Specifically, the uneven structure 45 may be provided in the region corresponding to the photodiode PD, of the light-receiving-side principal surface of the semiconductor substrate 12, without being provided in the region corresponding to the memory region MEM where light does not enter. That is, in the light-receiving-side principal surface of the semiconductor substrate 12, the region corresponding to the photodiode PD may have the uneven structure 45, and the region corresponding to the memory region MEM may be flat.

### 7. Sixth Embodiment

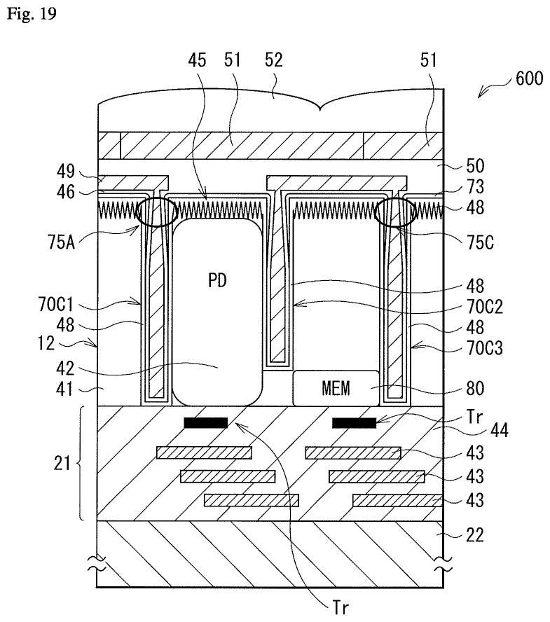

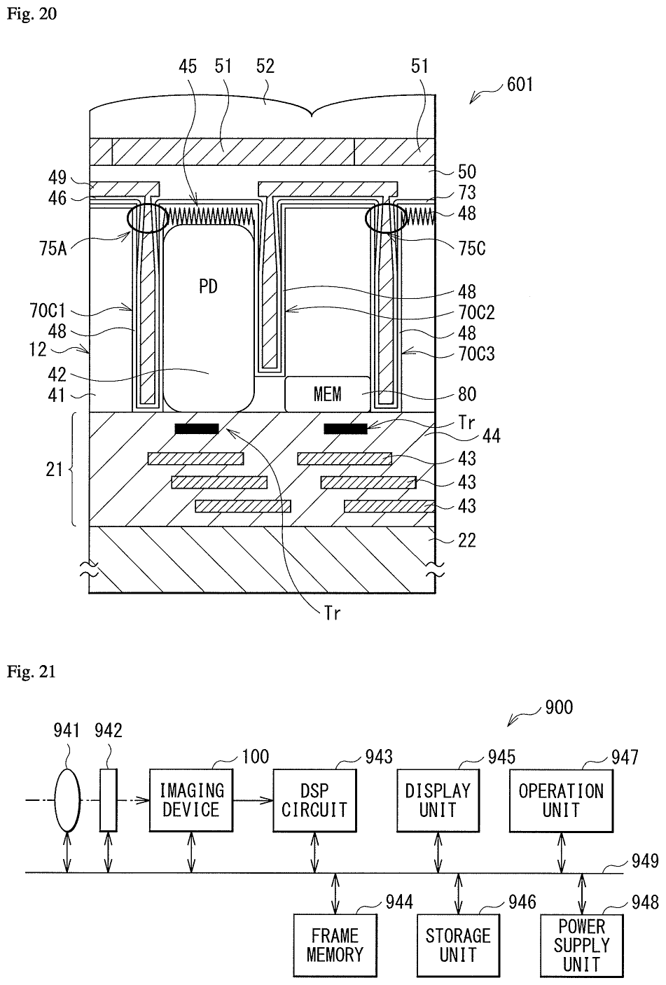

The following describes a configuration of the pixels 2 in an imaging device according to a sixth embodiment of the present disclosure with reference to FIGS. 19 and 20. FIG. 19 is a vertical cross-sectional view of an example of the configuration of the pixels 2 in the imaging device according to the present embodiment. FIG. 20 is a vertical cross-sectional view of a modification example of the configuration of the pixels 2 in the imaging device according to the present embodiment.

As illustrated in FIG. 19, an imaging device 600 according to the sixth embodiment is different from the imaging device 200 according to the second embodiment in that the imaging device 600 further includes the memory region MEM that holds a charge generated through the photoelectric conversion by the photodiodes PD.

The memory region MEM that holds charges accumulated in the photodiode PD and the pixel separation layers 70C1, 70C2, and 70C3 that block light entering the memory region MEM are as described in the fifth embodiment, and therefore description thereof is omitted here.

According to the present embodiment, the pixel separation layers 70C1 and 70C3 may be provided, for example, by forming apertures penetrating the semiconductor substrate 12 by etching from the principal surface that is opposite to the light-receiving-side principal surface of the semiconductor substrate 12, and by filling the resultant apertures with an insulating material and a light blocking material.

The apertures for the pixel separation layers 70C1 and 70C3 are formed from the principal surface that is opposite to the light-receiving-side principal surface of the semiconductor substrate 12, and thus the apertures may be provided either before or after the formation of the uneven structure 45. In a case where the aperture for the pixel separation layer 70B is formed after the formation of the uneven structure 45, therefore, the uneven structure 45 is formed at the vicinity section 75 of the pixel separation layer 70B. Meanwhile, in a case where the aperture for the pixel separation layer 70B is formed before the formation of the uneven structure 45, the vicinity section 75 of the pixel separation layer 70B is flat without formation of the uneven structure 45.

Furthermore, in an imaging device 601 according to the sixth embodiment, the uneven structure 45 on the light-receiving-side principal surface of the semiconductor substrate 12 may be provided only in a region corresponding to the photodiode PD as illustrated in FIG. 20.

Specifically, the uneven structure 45 may be provided in the region corresponding to the photodiode PD without being provided in a region corresponding to the memory region MEM where light does not enter, out of the light-receiving-side principal surface of the semiconductor substrate 12. That is, in the light-receiving-side principal surface of the semiconductor substrate 12, the region corresponding to the photodiode PD may have the uneven structure 45, and the region corresponding to the memory region MEM may be flat.

### 8. Application Examples

The following describes application examples of an imaging device according to an embodiment of the present disclosure with reference to FIGS. 21 to 26.

(Application to Imaging System)

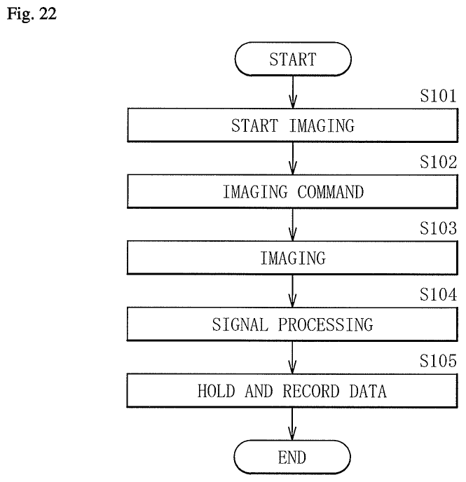

The following first describes an example of application of the imaging device according to an embodiment of the present disclosure to an imaging system with reference to FIGS. 21 to 22. FIG. 21 is a block diagram illustrating an example of a schematic configuration of an imaging system 900 including the imaging device 100 according to an embodiment of the present disclosure. FIG. 22 is a flowchart diagram illustrating an example of an imaging operation of the imaging system 900.

It is to be noted that, although the following description exemplifies the imaging device 100 according to the first embodiment of the present disclosure, the imaging devices according to the second to sixth embodiments are also applicable in the same manner.

As illustrated in FIG. 21, the imaging system 900 is, for example, an electronic apparatus. Examples of such an electronic apparatus include imaging apparatuses such as digital still cameras and video cameras, and mobile terminal apparatuses such as smartphones and tablet terminals.

The imaging system 900 includes, for example, a lens group 941, a shutter 942, the imaging device 100 according to an embodiment of the present disclosure, a DSP circuit 943, frame memory 944, a display unit 945, storage unit 946, an operation unit 947, and a power supply unit 948. In the imaging system 900, the imaging device 100, the DSP circuit 943, the frame memory 944, the display unit 945, the storage unit 946, the operation unit 947, and the power supply unit 948 are coupled to one another via a bus line 949.

The imaging device 100 outputs image data according to incident light that has passed through the lens group 941 and the shutter 942. The DSP circuit 943 is a signal processing circuit that processes a signal (i.e., the image data) outputted form the imaging device 100. The frame memory 944 temporarily holds the image data processed by the DSP circuit 943 on a per-frame basis. The display unit 945 is, for example, a panel display apparatus such as a liquid-crystal panel or an organic EL (Electro Luminescence) panel, and displays a moving image or a still image captured by the imaging device 100. The storage unit 946 includes a storage medium such as semiconductor memory and a hard disk, and records image data of the moving image or the still image captured by the imaging device 100. The operation unit 947 outputs operation commands for various functions of the imaging system 900 according to operations of a user. The power supply unit 948 is a various power source that supplies power to operate the imaging device 100, the DSP circuit 943, the frame memory 944, the display unit 945, the storage unit 946, and the operation unit 947.

The following then describes imaging procedures in the imaging system 900.

As illustrated in FIG. 22, a user gives an instruction to start imaging by operating the operation unit 947 (S101). This causes the operation unit 947 to transmit the imaging command to the imaging device 100 (S102). Upon receiving the imaging command, the imaging device 100 executes imaging in accordance with a predetermined imaging scheme (S103).

The imaging device 100 outputs captured image data to the DSP circuit 943. As used herein, the image data refers to data for all pixels of a pixel signal generated on the basis of charges accumulated in the photodiodes PD of the respective pixels 2. The DSP circuit 943 performs predetermined signal processing (e.g., a noise reducing process) on the image data outputted from the imaging device 100 (S104). The DSP circuit 943 causes the frame memory 944 to hold the image data that has undergone the predetermined signal processing. Thereafter, the frame memory 944 causes the storage unit 946 to store the image data (S105). In this manner, the imaging system 900 performs imaging.

In the present application example, the imaging device 100 according to an embodiment of the present disclosure is applied to the imaging system 900. The technique according to the present disclosure makes it possible to suppress reflection of incident light on the light-receiving-side principal surface of the semiconductor substrate 12, thus making it possible to suppress unintended light incidence into the photodiode PD. Therefore, according to the technique of the present disclosure, it is possible for the imaging system 900 to suppress occurrence of ghost, flare, and the like.

(Application to Mobile Body Control System)

The technique according to the present disclosure (the present technology) is applicable to various products. For example, the technique according to the present disclosure may be implemented as an apparatus to be mounted on a mobile body of any type, such as an automobile, an electric vehicle, a hybrid electric vehicle, a mo-torcycle, a bicycle, a personal mobility, an aircraft, a drone, a vessel, and a robot.

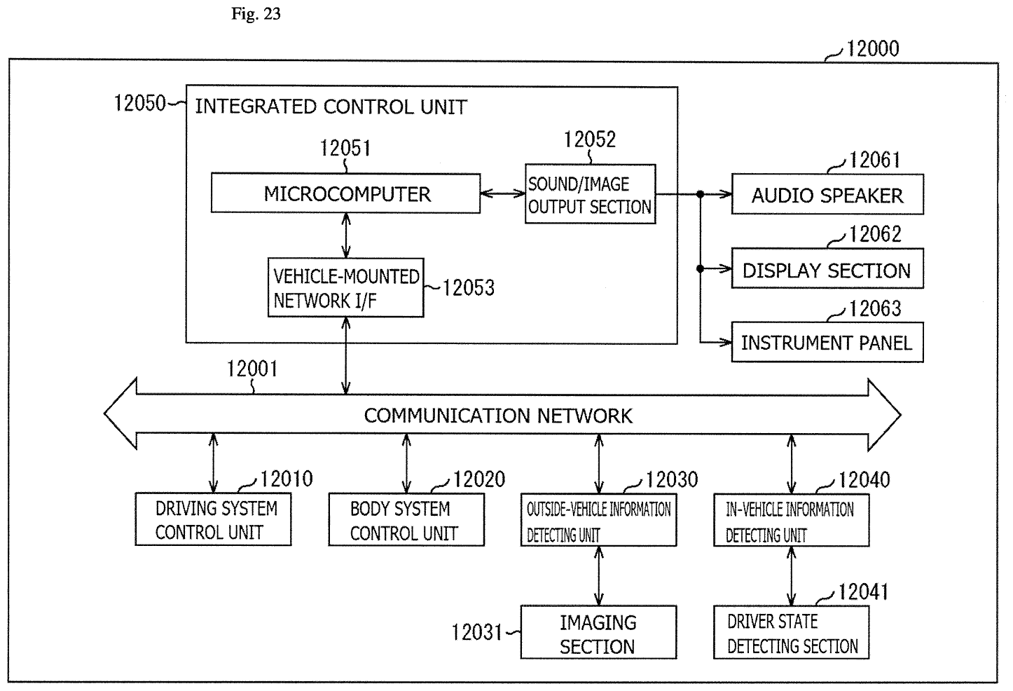

FIG. 23 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 23, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 23, an audio speaker 12061, a display section 12062, and an instrument panel 12063 are illustrated as the output device. The display section 12062 may, for example, include at least one of an on-board display and a head-up display.

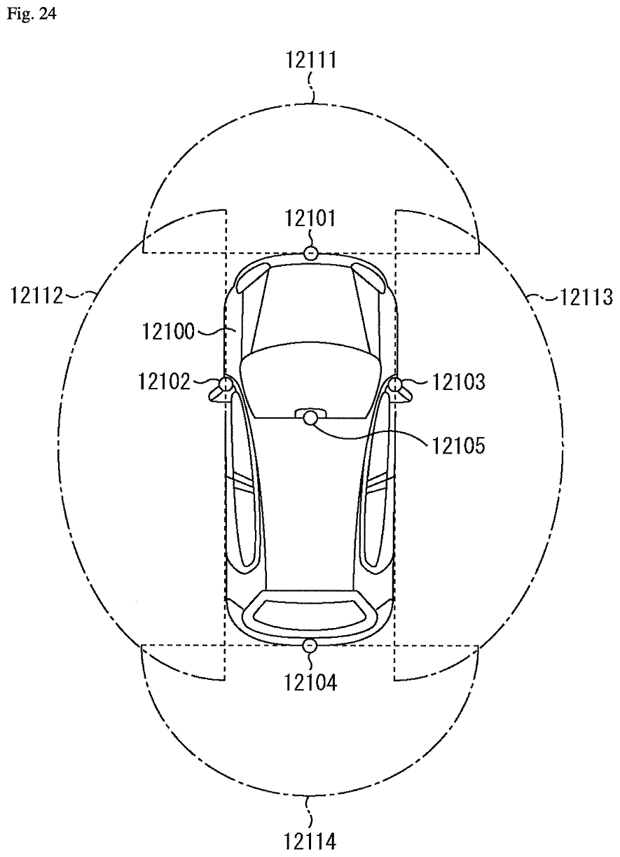

FIG. 24 is a diagram depicting an example of the installation position of the imaging section 12031.

In FIG. 24, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 24 depicts an example of photographing ranges of the imaging sections 12101 to 12104. An imaging range 12111 represents the imaging range of the imaging section 12101 provided to the front nose. Imaging ranges 12112 and 12113 re-spectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by super-imposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the mobile body control system to which the technology according to the present disclosure can be applied has been described above. The technology according to the present disclosure can be applied to the imaging section 12031 among the components described above. According to the technology of the present disclosure, it is possible to obtain a photographed image with higher image quality. Therefore, it is possible for the mobile body control system to perform control with high accuracy using the photographed image.

(Application to Endoscopic Surgery System)

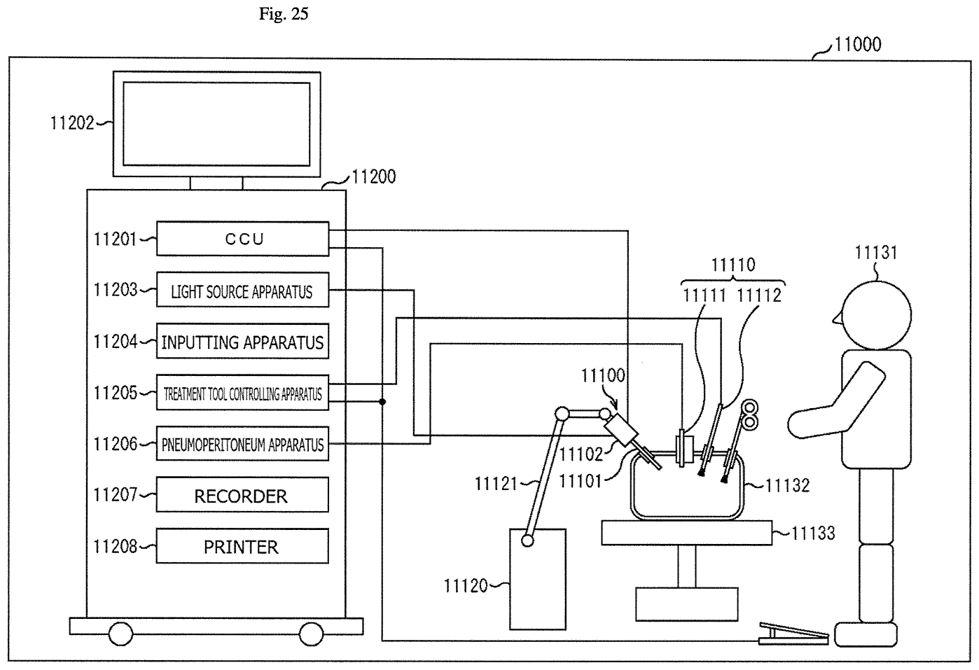

FIG. 25 is a view depicting an example of a schematic configuration of an endoscopic surgery system to which the technology according to an embodiment of the present disclosure (present technology) can be applied.

In FIG. 25, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photo-electrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as, for example, a light emitting diode (LED) and supplies irradiation light upon imaging of a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203. Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and syn-thesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

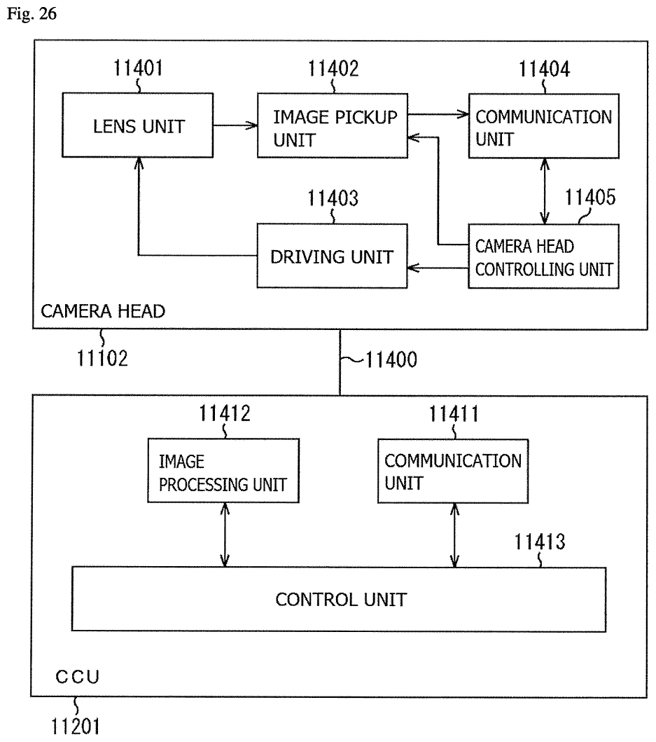

FIG. 26 is a block diagram depicting an example of a functional configuration of the camera head 11102 and the CCU 11201 depicted in FIG. 25.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. The image pickup unit 11402 may also be configured so as to have a pair of image pickup elements for acquiring respective image signals for the right eye and the left eye ready for three dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set auto-matically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technique according to the present disclosure can be applied has been described above. The technique according to the present disclosure can be preferably applied to the image pickup unit 11402 provided in the camera head 11102 of the endoscope 11100 among the components described above. According to the technique of the present disclosure, it is possible to further enhance the image quality of the image captured by the image pickup unit 11402. Therefore, it is possible to enhance visibility and operability of the user who uses the endoscopic surgery system.

The technique according to the present disclosure has been described above with reference to the first to sixth embodiments and the modification examples. However, the technique according to the present disclosure is not limited to the foregoing embodiments, etc., and may be modified in a wide variety of ways.

Furthermore, not all of the constituent elements and operations described in the embodiments are essential as constituent elements and operations of the present disclosure. For example, among the constituent elements of the embodiments, those that are not recited in any of the independent claims, which represent the broadest concepts of the present disclosure, are to be considered optional constituent elements.

The terms used throughout the present specification and the appended claims are to be construed as “open-ended” terms. For example, the term “include” and its grammatical variants are intended to be non-limiting, such that recitation of items in a list is not to the exclusion of other like items that can be substituted or added to the listed items. The term “have” and its grammatical variants are intended to be non-limiting, such that recitation of items in a list is not to the exclusion of other like items that can be substituted or added to the listed items.

It is to be noted that the terms used herein include a term that is simply used for convenience of description and does not limit a configuration and an operation. For example, the terms “right”, “left”, “upper”, and “lower” only indicate directions in the drawing that is referred to. Furthermore, the terms “inward” and “outward” re-spectively indicate a direction toward the center of a focused element and a direction away from the center of the focused element. The same applies to terms similar thereto and terms having similar meanings.

It is to be noted that the technique according to the present disclosure may be in any of the following configurations. According to the technique of the present disclosure including the following configurations, the uneven structure 45 that functions as a moth-eye structure enables further suppression of reflection of incident light on the light-receiving-side principal surface of the semiconductor substrate 12 including the photoelectric conversion section. Thus, the imaging device 100 is able to further suppress reflection of incident light inside the imaging device 100, thus making it possible to further suppress flare, ghost, or the like in a captured image. Effects of the technique according to the present disclosure are not necessarily limited to the effects described herein, and may be any of the effects described in the present disclosure.

(1)

An imaging device including:

a semiconductor substrate including a photoelectric conversion section provided for each of pixels that are two-dimensionally arranged, the photoelectric conversion section performing photoelectric conversion on incident light; and

an uneven structure provided on a light-receiving-side principal surface of the semiconductor substrate, the uneven structure including a plurality of pillars arranged at a period smaller than a wavelength of light belonging to a visible light band, each of the pillars having an aspect ratio of 1 or more as determined by dividing a height of each of the pillars by a diameter of a base of each of the pillars in an arbitrary direction.

(2)

The imaging device according to (1), in which each of the pillars has a flat part at a tip thereof, and the flat part has a diameter of 10 nm or less in an arbitrary direction.

(3)

An imaging device including:

a semiconductor substrate including a photoelectric conversion section provided for each of pixels that are two-dimensionally arranged, the photoelectric conversion section performing photoelectric conversion on incident light; and an uneven structure provided on a light-receiving-side principal surface of the semiconductor substrate, the uneven structure including a plurality of pillars arranged at a period smaller than a wavelength of light belonging to a visible light band, each of the pillars having a flat part at a tip thereof, the flat part having a diameter of 10 nm or less in an arbitrary direction.

(4)

The imaging device according to (3), in which each of the pillars has an aspect ratio of 1 or more as determined by dividing a height of each of the pillars by a diameter of a base of each of the pillars in an arbitrary direction.

(5)

The imaging device according to any one of (1) to (4), in which each of the pillars has a protruding shape that extends in a thickness direction of the semiconductor substrate.

(6)

The imaging device according to any one of (1) to (5), in which a tip of each of the pillars has a shape with a vertex or a hemispherical shape.

(7)

The imaging device according to any one of (1) to (6), in which the pillars are arranged on the light-receiving-side principal surface at a period of 200 nm or less.

(8)

The imaging device according to any one of (1) to (7), in which the pillars are arranged in a random arrangement, a square lattice arrangement, or a hexagonal close-packed arrangement on the light-receiving-side principal surface.

(9)

The imaging device according to any one of (1) to (8), in which the uneven structure is provided in a region, of the light-receiving-side principal surface, corresponding to the photoelectric conversion section.

(10)

The imaging device according to any one of (1) to (9), further including a first layer on the uneven structure, the first layer including a dielectric material.

(11)

The imaging device according to (10), further including a second layer on the first layer, the second layer including a material having a lower refractive index than the material included in the first layer.

(12)

The imaging device according to (10) or (11), in which the first layer is provided to fill an uneven portion of the uneven structure.

(13)

The imaging device according to (10), further including an interlayer insulating layer, in which

the first layer is provided along an uneven portion of the uneven structure, and the interlayer insulating layer fills the uneven portion of the uneven structure on the first layer.

(14)

The imaging device according to (11), in which the first layer is provided along an uneven portion of the uneven structure, and the second layer is provided to fill the uneven portion of the uneven structure.

(15)

The imaging device according to any one of (1) to (14), further including a pixel separation layer that separates the pixels that are adjacent from each other.

(16)

The imaging device according to (15), in which the pixel separation layer includes an insulating layer provided between the adjacent pixels and extending from the light-receiving-side principal surface in the thickness direction of the semiconductor substrate.

(17)

The imaging device according to (15) or (16), in which at least one of a plurality of the pixel separation layers is provided to penetrate the semiconductor substrate.

(18)

The imaging device according to (17), in which the light-receiving-side principal surface in vicinity of the pixel separation layer penetrating the semiconductor substrate is flat.

(19)

The imaging device according to any one of (1) to (18), in which the semiconductor substrate further includes a memory section that temporarily holds a charge generated through the photoelectric conversion by the photoelectric conversion section.

(20)

The imaging device according to (19), in which a light-receiving side of the memory section is covered with a light blocking section including a light blocking material.

### REFERENCE SIGNS LIST

2 pixel
3 pixel array section
4 vertical drive circuit
5 column signal processing circuit
6 horizontal drive circuit
7 output circuit
8 control circuit
10 pixel driving wiring line
11 horizontal signal line
12 semiconductor substrate
21 multi-layer wiring layer
22 support substrate
41 semiconductor region of first electrically-conductive type
42 semiconductor region of second electrically-conductive type
43 wiring layer
44 interlayer insulating layer
45, 45A, 45B, 45C uneven structure
46 interlayer insulating layer
47 pillar
48 pinning layer
49 light blocking section
50 planarizing film
51 color filter layer
52 on-chip lens
60 hardmask
70, 70A, 70B, 70C1, 70C2, 70C3 pixel separation film
73 antireflection layer
75 vicinity section
100, 100A, 200, 200A, 200B, 200C, 300, 301, 400, 401, 500, 501, 600, 601 imaging unit

What is claimed is:

1. An imaging device, comprising:
a semiconductor substrate including a photoelectric conversion section provided for each of pixels that are two-dimensionally arranged, the photoelectric conversion section performing photoelectric conversion on incident light; and
an uneven structure provided on a light-receiving-side principal surface of the semiconductor substrate, the uneven structure including a plurality of pillars arranged at a period smaller than a wavelength of light belonging to a visible light band,
each of the pillars having an aspect ratio of 1 or more as determined by dividing a height of each of the pillars by a diameter of a base of each of the pillars in an arbitrary direction.

2. The imaging device according to claim 1, wherein each of the pillars has a flat part at a tip thereof, and the flat part has a diameter of 10 nm or less in an arbitrary direction.

3. An imaging device, comprising:
a semiconductor substrate including a photoelectric conversion section provided for each of pixels that are two-dimensionally arranged, the photoelectric conversion section performing photoelectric conversion on incident light; and
an uneven structure provided on a light-receiving-side principal surface of the semiconductor substrate, the uneven structure including a plurality of pillars arranged at a period smaller than a wavelength of light belonging to a visible light band,
each of the pillars having a flat part at a tip thereof, the flat part having a diameter of 10 nm or less in an arbitrary direction.

4. The imaging device according to claim 3, wherein each of the pillars has an aspect ratio of 1 or more as determined by dividing a height of each of the pillars by a diameter of a base of each of the pillars in an arbitrary direction.

5. The imaging device according to claim 1, wherein each of the pillars has a protruding shape that extends in a thickness direction of the semiconductor substrate.

6. The imaging device according to claim 1, wherein a tip of each of the pillars has a shape with a vertex or a hemispherical shape.

7. The imaging device according to claim 1, wherein the pillars are arranged on the light-receiving-side principal surface at a period of 200 nm or less.

8. The imaging device according to claim 1, wherein the pillars are arranged in a random arrangement, a square lattice arrangement, or a hexagonal close-packed arrangement on the light-receiving-side principal surface.

9. The imaging device according to claim 1, wherein the uneven structure is provided in a region, of the light-receiving-side principal surface, corresponding to the photoelectric conversion section.

10. The imaging device according to claim 1, further comprising a first layer on the uneven structure, the first layer including a dielectric material.

11. The imaging device according to claim 10, further comprising a second layer on the first layer, the second layer including a material having a lower refractive index than the material included in the first layer.

12. The imaging device according to claim 10, wherein the first layer is provided to fill an uneven portion of the uneven structure.

13. The imaging device according to claim 10, further comprising an interlayer insulating layer, wherein
the first layer is provided along an uneven portion of the uneven structure, and
the interlayer insulating layer fills the uneven portion of the uneven structure on the first layer.

14. The imaging device according to claim 11, wherein
the first layer is provided along an uneven portion of the uneven structure, and
the second layer is provided to fill the uneven portion of the uneven structure.

15. The imaging device according to claim 1, further comprising a pixel separation layer that separates the pixels that are adjacent from each other.

16. The imaging device according to claim 15, wherein the pixel separation layer comprises an insulating layer provided between the adjacent pixels and extending from the light-receiving-side principal surface in a thickness direction of the semiconductor substrate.

17. The imaging device according to claim 15, wherein at least one of a plurality of the pixel separation layers is provided to penetrate the semiconductor substrate.

18. The imaging device according to claim 17, wherein the light-receiving-side principal surface in vicinity of the pixel separation layer penetrating the semiconductor substrate is flat.

19. The imaging device according to claim 1, wherein the semiconductor substrate further includes a memory section that temporarily holds a charge generated through the photoelectric conversion by the photo-electric conversion section.

20. The imaging device according to claim 19, wherein a light-receiving side of the memory section is covered with a light blocking section including a light blocking material.
